(19) United States
(12) Patent Application Publication
(10) Pub. No.: US 2024/0260320 A1
(43) Pub. Date: Aug. 1, 2024

(54) DISPLAY PANEL AND DISPLAY APPARATUS

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Bangqing XIAO, Beijing (CN); Chengjie QIN, Beijing (CN); Zhuoran YAN, Beijing (CN); Danyang BI, Beijing (CN); Qiwei WANG, Beijing (CN); Lili DU, Beijing (CN)

(21) Appl. No.: 18/005,691

(22) PCT Filed: Jan. 12, 2022
(86) PCT No.: PCT/CN2022/071675

§ 371 Date: Jan. 17, 2023

(51) Int. Cl. H10K 59/122; G09G 3/3233; H10K 59/121

(52) U.S. Cl. CPC H10K 59/122; G09G 3/3233; H10K 59/1213; G09G 2300/0452; G09G 2300/0819; G09G 2300/0852; G09G 2300/0861

(57) ABSTRACT

A display panel has a first display region, at least one second display region and a third display region. The display panel includes a substrate, an anode layer and a pixel definition layer. The anode layer is disposed on the substrate and includes a plurality of anodes. The pixel definition layer is disposed on a side of the anode layer away from the substrate. The pixel definition layer is provided with a plurality of openings therein, an opening corresponds to an anode, and the opening exposes at least a portion of the anode corresponding thereto. The first display region, the at least one second display region and the third display region are each provided with openings of the plurality of openings, and aperture ratios of the first display region, the at least one second display region and the third display region sequentially decrease.

### CROSS-REFERENCE TO RELATED APPLICATION

The present application is a national phase entry under 35 USC 371 of International Patent Application No. PCT/CN2022/071675, filed on Jan. 12, 2022, which is incorporated herein by reference in its entirety.

### TECHNICAL FIELD

The present disclosure relates to the field of display technologies, and in particular, to a display panel and a display apparatus.

### BACKGROUND

In order to improve a visual effect of a display screen, it is necessary to improve a proportion of a display region in the display screen as much as possible, i.e., to improve a screen-to-body ratio of the display screen. A display screen with a screen-to-body ratio of 100% or approximately 100% is generally referred to as a full screen.

At present, an under-screen camera technology is applied to a full screen of a display apparatus. That is, a camera is disposed below the display screen, so that a region where the camera is located is also used for performing display, and the front camera is prevented from occupying an area of a display region of the display screen. As a result, a screen-to-body ratio of the display screen is close to or reaches 100%, thereby achieving the full screen.

### SUMMARY

In an aspect, a display panel is provided. The display panel has a first display region, at least one second display region and a third display region; the at least one second display region is located between the first display region and the third display region, the first display region at least partially surrounds the at least one second display region, and the at least one second display region at least partially surrounds the third display region.

The display panel includes a substrate, an anode layer and a pixel definition layer.

The anode layer is disposed on the substrate, and the anode layer includes a plurality of anodes. The pixel definition layer is disposed on a side of the anode layer away from the substrate. The pixel definition layer is provided with a plurality of openings therein, an opening corresponds to an anode, and the opening exposes at least a portion of the anode corresponding to the opening.

The first display region, the at least one second display region and the third display region are each provided with openings of the plurality of openings, and aperture ratios of the first display region, the at least one second display region and the third display region sequentially decrease.

In some embodiments, the display panel includes a plurality of second display regions that are sequentially nested. Aperture ratios of the plurality of second display regions sequentially decrease in a direction from the first display region to the third display region.

In some embodiments, the display panel includes a plurality of sub-pixels capable of emitting light of a plurality of colors, and the opening is used for defining a light-emitting region of a sub-pixel. The plurality of openings of the pixel definition layer include first openings, second openings and third openings, the first openings are disposed in the first display region, the second openings are disposed in the at least one second display region, and the third openings are disposed in the third display region. Areas of orthogonal projections, on the substrate, of a first opening, a second opening and a third opening corresponding to sub-pixels emitting light of a same color sequentially decrease.

In some embodiments, the display panel includes a plurality of second display regions that are sequentially nested. In the second openings disposed in the plurality of second display regions, areas of orthogonal projections, on the substrate, of second openings corresponding to sub-pixels emitting light of a same color sequentially decrease in a direction from the first display region to the third display region.

In some embodiments, in a plurality of display regions consisting of the first display region, the at least one second display region and the third display region, a difference between areas of orthogonal projections, on the substrate, of openings, that are respectively located in every two adjacent display regions and corresponds to sub-pixels emitting light of a same color is ΔS, and each ΔS has an approximately equal value.

In some embodiments, a distribution density of the openings in the first display region, a distribution density of the openings in the at least one second display region and a distribution density of the openings in the third display region sequentially decrease.

In some embodiments, the display panel includes a plurality of second display regions that are sequentially nested. Distribution densities of openings respectively disposed in the plurality of second display regions sequentially decrease in a direction from the first display region to the third display region.

In some embodiments, the display panel further includes a plurality of pixel circuits disposed between the substrate and the anode layer, and a pixel circuit is electrically connected to at least one anode. The plurality of pixel circuits include first pixel circuits, second pixel circuits and third pixel circuits; the first pixel circuits are each electrically connected to at least one anode disposed in the first display region, the second pixel circuits are each electrically connected to anodes disposed in the at least one second display region, and the third pixel circuits are each electrically connected to anodes disposed in the third display region.

The at least one second display region includes a setting second display region, and a second pixel circuit electrically connected to anodes disposed in the setting second display region is a setting second pixel circuit. A number of the anodes electrically connected to the setting second pixel circuit is greater than a number of anodes electrically connected to a first pixel circuit, and is less than a number of anodes electrically connected to a third pixel circuit.

In some embodiments, the first pixel circuit is electrically connected to one anode, the setting second pixel circuit is electrically connected to two or three anodes, and the third pixel circuit is electrically connected to at least three anodes.

In some embodiments, the at least one second display region further Includes a general second display region; the general second display region is located between the first display region and the setting second display region, and a second pixel circuit electrically connected to at least one anode disposed in the general second display region is a general second pixel circuit. A number of anodes electrically connected to the general second pixel circuit is equal to the number of anodes electrically connected to the first pixel circuit.

In some embodiments, the display pan& includes a plurality of sub-pixels capable of emitting light of a plurality of colors, and a sub-pixel includes a single anode. Sub-pixels to which the anodes electrically connected to the setting second pixel circuit respectively belong emit light of a same color; and/or sub-pixels to which the anodes electrically connected to the third pixel circuit respectively belong emit light of another same color.

In some embodiments, the setting second pixel circuit is electrically connected to two anodes respectively included in two sub-pixels that are adjacent in a first direction and emit the light of the same color. The third pixel circuit is electrically connected to four anodes respectively included in four sub-pixels that are adjacent and emit the light of the same color; and the four anodes are arranged in two columns in the first direction, and are arranged in two rows in a second direction. The first direction is perpendicular to the second direction.

In some embodiments, the display panel includes a plurality of second display regions that are sequentially nested. The display panel further includes a plurality of pixel circuits that are disposed between the substrate and the anode layer. The plurality of pixel circuits are disposed in the first display region; alternatively, the plurality of pixel circuits are disposed in the first display region and at least one second display region of the plurality of second display regions.

At least one second display region provided with pixel circuits of the plurality of second display regions is closer to first display region than another at least one second display region provided with no pixel circuit of the plurality of second display regions.

In some embodiments, in a plurality of display regions consisting of the first display region, the at least one second display region and the third display region, a display region provided with pixel circuits of the plurality of pixel circuits is a first transmittance region, and a display region provided with no pixel circuit is a second transmittance region.

The display panel further includes at least one connection layer disposed between the plurality of pixel circuits and the anode layer, and the at least one connection layer includes a plurality of first connection patterns and a plurality of first connection lines.

The plurality of anodes include a plurality of first anodes and a plurality of second anodes, the plurality of first anodes are disposed in the first transmittance region, and the plurality of second anodes are disposed in the second transmittance region. A first anode is electrically connected to a respective pixel circuit via at least one first connection pattern, and a second anode is electrically connected to a respective pixel circuit via at least one first connection line.

In some embodiments, the display panel includes a plurality of connection layers. The first anode is electrically connected to the respective pixel circuit via first connection patterns of the plurality of first connection patterns, and the first connection patterns of the plurality of first connection patterns are respectively located in the plurality of connection layers; orthographic projections, on the substrate, of any two first connection patterns, that are adjacent in a direction parallel to a thickness direction of the substrate, of the first connection patterns of the plurality of first connection patterns at least partially overlap.

In some embodiments, the at least one connection layer includes a first connection layer and a second connection layer, and the first connection layer is farther away from the substrate than the second connection layer. The first connection line used for being electrically connected to the second anode and the respective pixel circuit is located in the first connection layer. The second connection layer includes a second connection pattern, and the first connection line is electrically connected to the respective pixel circuit via the second connection pattern.

In some embodiments, each of at least one pixel circuit is electrically connected to at least two anodes of the plurality of anodes. The at least one connection layer further includes a plurality of second connection lines, at least two anodes electrically connected to a same pixel circuit are electrically connected to each other via at least one second connection line, and one of the at least two anodes electrically connected to the same pixel circuit is electrically connected to a respective pixel circuit via a first connection pattern or a first connection line.

in some embodiments, the at least one connection layer further includes at least two third connection patterns, and the at least two anodes electrically connected to the same pixel circuit are electrically connected to the at least two third connection patterns, respectively. The second connection line used for being electrically connected to the at least two anodes is disposed in a same connection layer as the at least two third connection patterns, and is electrically connected to the at least two third connection patterns.

In some embodiments, the display panel includes a plurality of connection layers, and the plurality of first connection lines and the plurality of second connection lines are located in different connection layers.

In some embodiments, the plurality of pixel circuits include a plurality of circuit units, and a circuit unit includes a plurality of first-type pixel circuits and a second-type pixel circuit that are sequentially arranged in a second direction; a first-type pixel circuit is electrically connected to at least one first anode, and the second-type pixel circuit is electrically connected to second anodes of the plurality of second anodes.

In some embodiments, the display panel further includes a second initialization signal line and a third initialization signal line. In the circuit unit, the plurality of first-type pixel circuits are electrically connected to the second initialization signal line, and the second-type pixel circuit is electrically connected to the third initialization signal line.

In some embodiments, orthogonal projections, on the substrate, of the first openings are each in a shape of a polygon; orthogonal projections, on the substrate, of the second openings are each in a shape of a polygon, a circle or an ellipse; orthogonal projections, on the substrate, of the third openings are each in a shape of a circle or an ellipse.

In some embodiments, the display panel includes two second display regions that are nested. In openings corresponding to the sub-pixels emitting the light of the same color, a ratio of areas of the first opening, a second opening disposed in a second display region closer to the first display region, a second opening disposed in a second display region farther away from the first display region, and the third opening is in a range from 1:0.8:0.6:0.5 to 1:0.9:0.8:0.5.

In some embodiments, the display panel includes a pixel circuit layer disposed between the substrate and the anode layer, and the pixel circuit layer includes an active layer, a first gate conductive layer and a second gate conductive layer that are arranged in sequence in a third direction; the third direction is parallel to a thickness direction of the substrate, and is from the substrate to the anode layer.

The pixel circuit layer includes a plurality of pixel circuits, and each of at least one pixel circuit includes a compensation transistor; the compensation transistor includes a semiconductor pattern disposed in the active layer and two gates disposed in the first gate conductive layer.

The semiconductor pattern includes first portions and a second portion, orthographic projections of the first portions on the substrate overlap with orthographic projections of the two gates of the compensation transistor on the substrate, respectively; an orthographic projection of the second portion on the substrate is located between the orthographic projections of the two gates of the compensation transistor on the substrate.

The second gate conductive layer includes a first initialization signal line, a light shielding pattern and a connection portion; the connection portion is connected to the first initialization signal line and the light shielding pattern, and an orthographic projection of the light shielding pattern on the substrate overlaps with the orthographic projection of the second portion of the semiconductor pattern on the substrate.

In some embodiments, the pixel circuit further includes a first reset transistor, and the first reset transistor includes two gates disposed in the first gate conductive layer.

Each of at least one anode includes a main body portion, and two protruding portions respectively located on two sides of the main body portion in a second direction. An orthographic projection of the main body portion on the substrate is located between orthographic projections of first reset transistors of two pixel circuits arranged in the second direction on the substrate; in the protruding portion and the first reset transistor that are located on a same side of the main body portion, an orthographic projection of the protruding portion on the substrate at least partially overlaps with orthographic projections of the two gates of the first reset transistor on the substrate.

In another aspect, a display apparatus is provided. The display apparatus includes the display panel as described in any one of the above embodiments.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art can obtain other drawings according to these drawings. In addition, the accompanying drawings in the following description may be regarded as schematic diagrams, and are not limitations on actual sizes of products, actual processes of methods and actual timings of signals involved in the embodiments of the present disclosure.

FIG. 1 is a top view of a display apparatus, in accordance with some embodiments;

FIG. 2a is a top view of a display panel, in accordance with some embodiments;

FIG. 2b is a top view of another display panel, in accordance with some embodiments;

FIG. 2c is a top view of yet another display panel, in accordance with some embodiments;

FIG. 3 is a diagram showing a structure corresponding to the region B in FIG. 2a;

FIG. 4 is a section view taken along the section line C-C′ in FIG. 3;

FIG. 5 is an equivalent circuit diagram of a pixel circuit, in accordance with some embodiments;

FIG. 6a is a structural diagram of an active layer, in accordance with some embodiments;

FIG. 6b is a structural diagram of another active layer, in accordance with some embodiments;

FIG. 6c is a structural diagram of yet another active layer, in accordance with some embodiments;

FIG. 7 is a structural diagram of a first gate conductive layer, in accordance with some embodiments;

FIG. 8 is a diagram showing a structure of which a first gate conductive layer is stacked on an active layer, in accordance with some embodiments;

FIG. 9 is a structural diagram of a second gate conductive layer, in accordance with some embodiments;

FIG. 10 is a diagram showing a structure of which a second gate conductive layer is stacked on a first gate conductive layer, in accordance with some embodiments;

FIG. 11 is a diagram showing a structure of which an interlayer dielectric layer is stacked on a second gate conductive layer, in accordance with some embodiments;

FIG. 12 is a structural diagram of a first source-drain conductive layer, in accordance with some embodiments;

FIG. 13 is a diagram showing a structure of which a first source-drain conductive layer is stacked on an interlayer dielectric layer, in accordance with some embodiments;

FIG. 14 is a diagram showing a structure of which a first planarization layer is provided on a first source-drain conductive layer, in accordance with some embodiments;

FIG. 15 is a structural diagram of a second source-drain conductive layer, in accordance with some embodiments;

FIG. 16 is a diagram showing a structure of which a second source-drain conductive layer is stacked on a first planarization layer, in accordance with some embodiments;

FIG. 17 is a diagram showing a structure of which a second planarization layer is provided on a second source-drain conductive layer, in accordance with some embodiments;

FIG. 18 is a diagram showing a structure of which an anode layer is provided on a second planarization layer, in accordance with some embodiments;

FIG. 19 is a diagram showing a structure of which a pixel definition layer is stacked on an anode layer, in accordance with some embodiments;

FIG. 20 is a diagram showing a structure of which a connection layer is stacked on a second planarization layer, in accordance with some embodiments;

FIG. 21 is a diagram showing a structure of which a third planarization layer is stacked on a connection layer, in accordance with some embodiments;

FIG. 22 is a diagram showing a structure of which an anode layer is stacked on a third planarization layer, in accordance with some embodiments;

FIG. 23 is a diagram showing another structure corresponding to the region B in FIG. 2a;

FIG. 24 is a diagram showing yet another structure corresponding to the region B in FIG. 2a;

FIG. 25 is a diagram showing a structure corresponding to the region D in FIG. 24;

FIG. 26 is a diagram showing another structure corresponding to the region D in FIG. 24;

FIG. 27 is a diagram showing yet another structure corresponding to the region B in FIG. 2a;

FIG. 28 is a diagram showing yet another structure corresponding to the region B in FIG. 2a;

FIG. 29 is a diagram showing yet another structure corresponding to the region B in FIG. 2a;

FIG. 30 is a diagram showing yet another structure corresponding to the region B in FIG. 2a;

FIG. 31a is a section view taken along the section line E-E′ in FIG. 30;

FIG. 31b is another section view taken along the section line E-E′ in FIG. 30;

FIG. 32 is a diagram showing yet another structure corresponding to the region B in FIG. 2a;

FIG. 33a is a section view taken along the section line H-H′ in FIG. 32;

FIG. 33b is a section view taken along the section line in FIG. 32;

FIG. 33c is another section view taken along the section line J-J′ in FIG. 32;

FIG. 34 is a diagram showing another structure of which a first source-drain conductive layer is stacked on an interlayer dielectric layer, in accordance with some embodiments;

FIG. 35 is a diagram showing another structure of which a first gate conductive layer is stacked on an active layer, in accordance with some embodiments;

FIG. 36 is a structural diagram of another second gate conductive layer, in accordance with some embodiments;

FIG. 37 is a diagram showing another structure of which a second gate conductive layer is stacked on a first gate conductive layer, in accordance with some embodiments;

FIG. 38 is a structural diagram of an anode layer, in accordance with some embodiments;

FIG. 39 is a diagram showing another structure of which an anode layer is stacked on a second planarization layer, in accordance with some embodiments;

FIG. 40 is a structural diagram of another anode layer, in accordance with some embodiments; and

FIG. 41 is a diagram showing yet another structure of which an anode layer is stacked on a second planarization layer, in accordance with some embodiments.

### DETAILED DESCRIPTION

Technical solutions in some embodiments of the present disclosure will be described clearly and completely below with reference to the accompanying drawings. Obviously, the described embodiments are merely some but not all embodiments of the present disclosure. AH other embodiments obtained by a person of ordinary skill in the art based on the embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment', some embodiments”, “exemplary embodiments”, “example, “specific example” or some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a plurality of” or “the plurality of” means two or more unless otherwise specified.

In the description of some embodiments, the terms such as “electrically connected” and “connected” and derivatives thereof may be used. For example, the term “electrically connected” may be used in the description of some embodiments to indicate that two or more components are in direct physical or electrical contact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term such as “about”, “substantially” or “approximately” includes a stated value and an average value within an acceptable range of deviation of a particular value. The acceptable range of deviation is determined by a person of ordinary skill in the art in view of measurement in question and errors associated with measurement of a particular quantity (i.e., limitations of a measurement system).

In the description of the present disclosure, it will be understood that, orientations or positional relationships indicated by the terms such as “center”, “longitudinal”, “transverse”, “length”, “width”, “vertical”, “horizontal”, “inner” and “outer” are based on orientations or positional relationships shown in the accompanying drawings, which are merely for facilitating and simplifying the description of the present disclosure, and are not for indicating or implying that apparatuses or elements that are referred to must have a particular orientation and be constructed or operated in the particular orientation. Therefore, the orientations or the positional relationships indicated thereby cannot be understood as limitations of the present disclosure.

It will be understood that, in a case where a layer or an element is referred to as being on another layer or a substrate, it may be that the layer or the element is directly on the another layer or the substrate, or there may be a middle layer between the layer or the element and the another layer or the substrate.

Exemplary embodiments are described herein with reference to sectional views and/or plan views as idealized exemplary drawings. In the accompanying drawings, thicknesses of layers and sizes of regions are enlarged for clarity. Thus, variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of regions in a device, and are not intended to limit the scope of the exemplary embodiments.

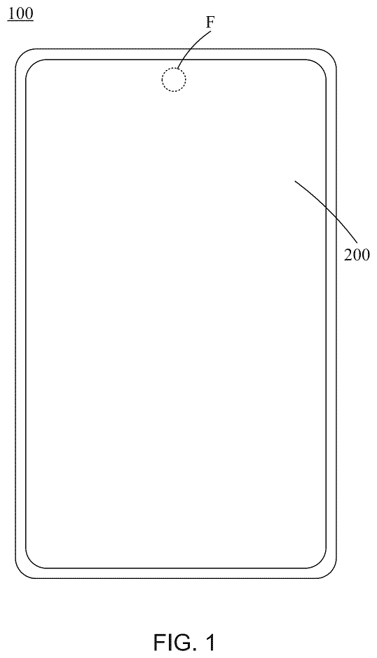

FIG. 1 is a top view of a display apparatus provided in some embodiments of the present disclosure. The display apparatus 100 may be any apparatus that displays text or images whether in motion (e.g., a video) or stationary (e.g., a still image). More specifically, it is anticipated that the embodiments may be implemented in a variety of electronic apparatuses or associated with a variety of electronic apparatuses. The variety of electronic apparatuses are, but are not limited to, mobile phones, wireless apparatuses, personal data assistants (PDAs), hand-held or portable computers, global positioning system (GPS) receivers/navigators, cameras, moving picture experts group 4 (MP4) video players, video cameras, game consoles, watches, clocks, calculators, television monitors, flat panel displays, computer monitors, automobile displays (e.g., odometer displays), navigators, cockpit controllers and/or displays, camera view displays (e.g., displays of rear-view cameras in vehicles), electronic photos, electronic billboards or signs, projectors, building structures, packaging and aesthetic structures (e.g., displays for displaying an image of a piece of jewelry). FIG. 1 is described by taking an example where the display apparatus 100 is a mobile phone.

A technology in which a functional device is provided on a back side of a screen (a side away from a light exit surface of the screen) is applied to the display apparatus 100. The functional device is, for example, a front-facing camera assembly, an under-screen fingerprint assembly, a three-dimensional (3D) face identification assembly, an iris identification assembly, a proximity sensor and other device capable of achieving a particular function. A technology in which the front-facing camera assembly is provided on the back side of the screen is an under-screen camera technology.

As shown in FIG. 1, the display apparatus 100 includes a display panel 200, and the display panel 200 may be an organic light-emitting diode (OLED) display panel.

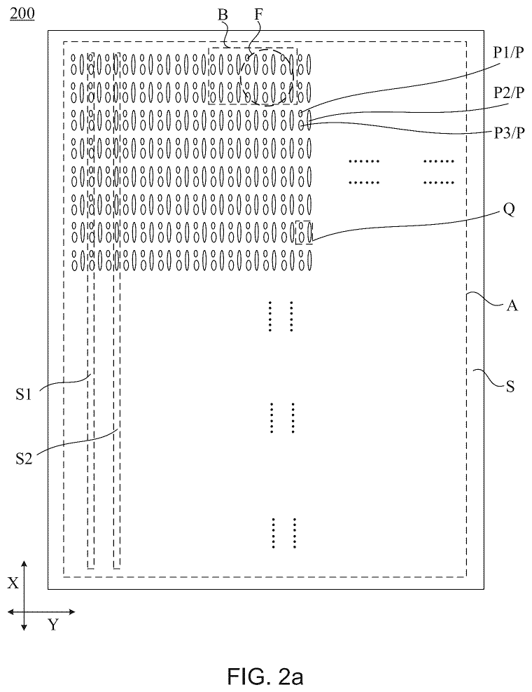

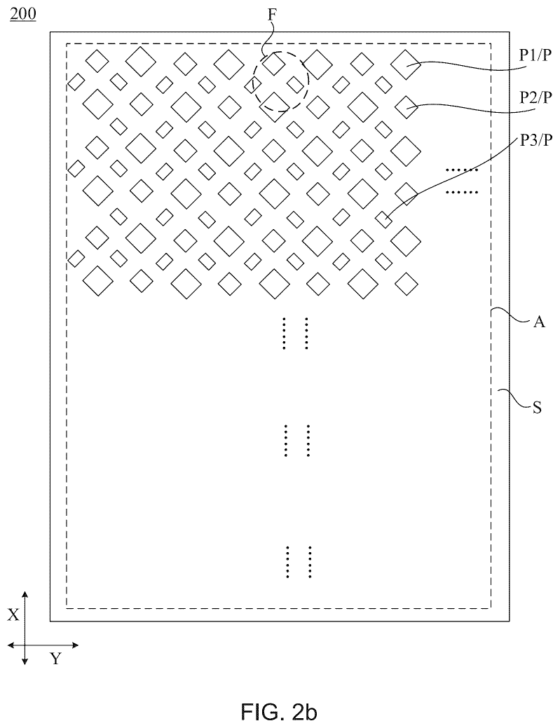

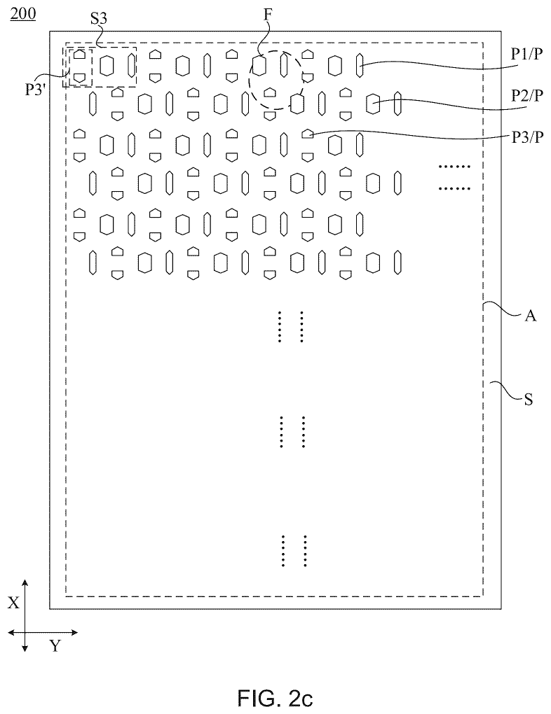

FIGS. 2a to 2c are each a top view of the display panel 200 provided in some embodiments of the present disclosure. As shown in FIG. 2a, the display panel 200 includes a main display area A, a functional device area F and a bezel region S surrounding the main display area A. The functional device is disposed in the functional device area F and located on a back side of the display panel 200, and the functional device needs to receive light from outside during working. In order to improve a sensitivity of the functional device, it is necessary to ensure that the functional device are able to receive a sufficient amount of light, and it is necessary to improve a light transmittance of a portion of the display panel 200 located in the functional device area F.

As shown in FIG. 2a, the display panel 200 includes a plurality of pixels Q arranged in an array. Each pixel Q includes sub-pixels P.

A plurality of sub-pixels P may be arranged in different arrangements.

For example, as shown in FIG. 2a, the plurality of sub-pixels P are divided into a plurality of first pixel columns S1 and a plurality of second pixel columns S2, the first pixel columns S1 and the second pixel columns S2 each extend in a first direction X, and the plurality of first pixel columns S1 and the plurality of second pixel columns S2 are alternately arranged in a second direction Y.

The first pixel column S1 includes a plurality of first sub-pixels P1 and a plurality of third sub-pixels P3 alternately arranged in the first direction X, and the second pixel column S2 includes a plurality of second sub-pixels P2 sequentially arranged in the first direction X.

For example, as shown in FIG. 2b, the plurality of sub-pixels P are arranged in a “Diamond” arrangement. For example, in the plurality of sub-pixels P, first sub-pixels P1 and second sub-pixels P2 are alternately arranged in the first direction X, the first sub-pixels P1 and the second sub-pixels P2 are also alternately arranged in the second direction Y, and third sub-pixels P3 are arranged in an array in both the first direction X and the second direction Y.

For example, in the plurality of sub-pixels arranged in the “Diamond” arrangement, the sub-pixels P are each in a shape of a rectangle, one of diagonal lines of the rectangle extends in the first direction X, and the other of the diagonal lines extends in the second direction Y.

For example, in the plurality of sub-pixels arranged in the “Diamond” arrangement, the sub-pixels P are each substantially in a shape of a rectangle. For example, four corners of the rectangle are each a curved corner.

For example, in the plurality of sub-pixels arranged in the “Diamond” arrangement, at least one type of sub-pixels P are each substantially in a shape of a sector, and centers of the sectors are arranged in the second direction.

For example, as shown in FIG. 2c, the plurality of sub-pixels P are arranged in a “GGRB” arrangement. For example, the plurality of sub-pixels P are divided into a plurality of pixel units S3, and the plurality of pixel units S3 are arranged in an array.

Each pixel unit S3 includes a third pixel group P3′, and the third pixel group P3′ includes two third sub-pixels P3 arranged in the first direction X. In each pixel unit S3, the third pixel group P3′, a second sub-pixel P2 and a first sub-pixel P1 are sequentially arranged in the second direction Y.

In any one of the above embodiments, each sub-pixel P may emit one of blue light, green light, red light or white light. Moreover, the first sub-pixel P1, the second sub-pixel P2 and the third sub-pixel P3 emit light of different colors, respectively.

The first direction X intersects the second direction Y. For example, the first direction X and the second direction Y may be perpendicular to each other.

It will be noted that the first direction X may be a longitudinal direction of the display apparatus 100, and the second direction Y may be a transverse direction of the display apparatus 100; alternatively, the first direction X may be a column direction in which the plurality of pixels Q are arranged in the array, and the second direction Y may be a row direction in which the plurality of pixels are arranged in the array.

The accompanying drawings of the present disclosure are merely described by taking an example where the first direction X is the column direction, and the second direction Y is the row direction. In the embodiments of the present disclosure, technical solutions obtained by rotating the accompanying drawings at a certain angle (e.g., 30 degrees, 45 degrees or 90 degrees) are also with the protection scope of the present disclosure.

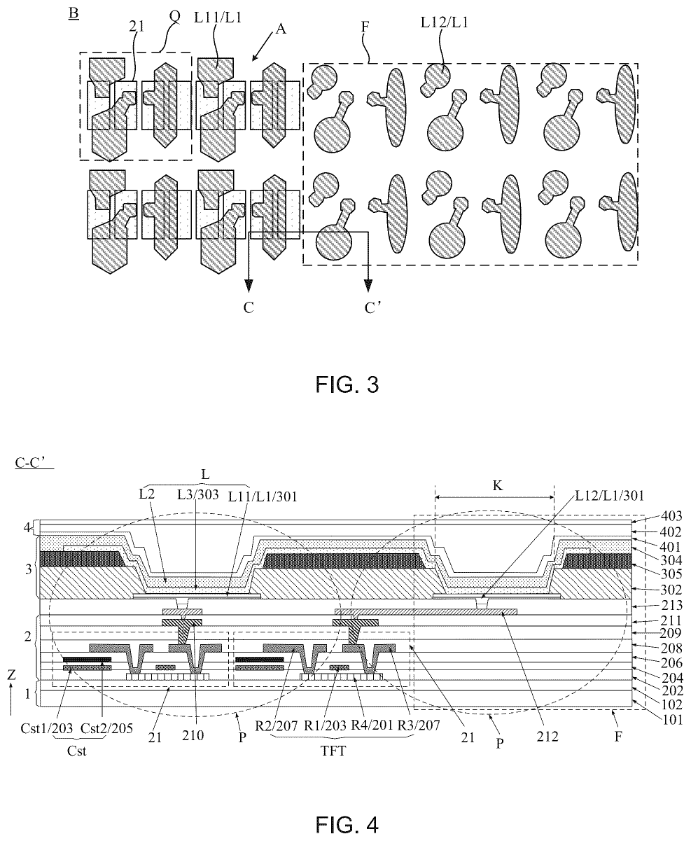

FIG. 3 shows a structural diagram of a region where the dashed box B in FIG. 2a is located. As shown in FIG. 3, each sub-pixel P includes a pixel circuit 21 and an anode L1. The anodes L1 include first anodes L11 and second anodes L12.

Referring to FIG. 3, in order to improve the light transmittance of a portion of the display panel 200 located in the functional device area F, pixel circuits 21 connected to the second anodes L12 are disposed in a region except for the functional device area F of the display panel 100. For example, the pixel circuits 21 are disposed in the main display area A. That is, the functional device area F is provided with no pixel circuit 21 but only the second anodes L12, which may prevent the light transmittance from being reduced due to a blocking effect, on light, of metal film layers in the pixel circuit 21.

FIG. 4 shows a section view taken along the section line C-C′ in FIG. 3. As shown in FIG. 4, the display panel 200 includes a substrate 1, and a pixel circuit layer 2, a light-emitting device layer 3 and an encapsulation layer 4 that are arranged on the substrate 1 in sequence.

The substrate 1 may be of a single-layer structure or a multi-layer structure. For example, as shown in FIG. 4. the substrate 1 may include a flexible base layer 101 and a buffer layer 102 that are sequentially stacked. For another example, the substrate 1 may include a plurality of flexible base layers 101 and a plurality of buffer layers 102 that are alternately arranged. A material of the flexible base layer 101 may include polyimide, and a material of the buffer layer 102 may include silicon nitride and/or silica, so that effects of blocking moisture and oxygen and blocking basic ions are achieved.

The pixel circuit layer 2 includes an active layer 201, a first gate insulating layer 202, a first gate conductive layer 203, a second gate insulating layer 204, a second gate conductive layer 205, an interlayer dielectric layer 206, a first source-drain conductive layer 207, a passivation layer 208, a first planarization layer 209, a second source-drain conductive layer 210 and a second planarization layer 211 that are sequentially stacked on the substrate 1.

Optionally, there may be a single source-drain conductive layer (e.g., only the first source-drain conductive layer 207 or the second source-drain conductive layer 210), and a planarization layer has only a single layer (e.g., only the first planarization layer 209 or the second planarization layer 211) accordingly.

The pixel circuit layer 2 includes a plurality of pixel circuits 21, and each sub-pixel P includes a respective pixel circuit 21.

Each pixel circuit 21 is provided with a plurality of thin film transistors TFT and a plurality of capacitance structures Cst. FIG, 4 shows only two thin film transistors TFT and two respective capacitance structures Cst as an example.

A thin film transistor TFT includes a gate R1, a source R2, a drain R3 and an active layer pattern R4. The gate R1 is located in the first gate conductive layer 203, the source R2 and the drain R3 are both located in the first source-drain conductive layer 207, and the active layer pattern R4 is located in the active layer 201.

A capacitance structure Cst includes a first plate Cst1 and a second plate Cst2, the first plate Cst1 is located in the first gate conductive layer 203, and the second plate Cst2 is located in the second gate conductive layer 205.

Referring to FIG. 4, the functional device area F is provided with no pixel circuit 21.

The light-emitting device layer 3 includes an anode layer 301, a pixel definition layer 302, a light-emitting functional layer 303 and a cathode layer 304 that are sequentially stacked on a side of the pixel circuit layer 2 away from the substrate 1,

The light-emitting device layer 3 is provided with a plurality of light-emitting devices L therein. A light-emitting device L includes an anode L1 located in the anode layer 301, a cathode L2 located in the cathode layer 304 and a light-emitting pattern L3 located in the light-emitting functional layer 303. The cathode L2 located in the cathode layer 304 is configured to transmit a low-level voltage VSS.

For example, in addition to the light-emitting pattern L3, the light-emitting functional layer 303 further includes one or more of an electron transporting layer (ETL), an electron injection layer (EIL), a hole transporting layer (HTL) and a hole injection layer (HIL).

For example, the anode L1 may be electrically connected to the source R2 or he drain R3 of the thin film transistor TFT.

For example, the pixel definition layer 302 is provided with a plurality of openings K therein, at least a portion of the light-emitting pattern L3 is located in an opening K, and light generated by a respective sub-pixel P is emitted to the outside through the opening K.

For example, a support layer 305 may be provided between the pixel definition layer 302 and a second electrode layer 304, and the support layer 305 may function to support a protective film layer, so as to avoid a breakage, caused by which the protective film layer is in contact with a first electrode layer 301 or other wirings, of the first electrode layer 301 or the other wirings.

Optionally, the pixel circuit layer 2 and the light-emitting device layer 3 are provided a connection layer 212 and a third planarization layer 213 therebetween.

For example, the connection layer 212 and the third planarization layer 213 may each be of a multi-layer structure.

For example, the anode L1 may be electrically connected to the source R2 or the drain R3 of the thin film transistor TFT indirectly via the connection layer 212 and the second source-drain conductive layer 210.

For example, referring to FIG. 4, the first anode L11 is electrically connected to the second source-drain conductive layer 210 via a connection pattern located in the connection layer 212, and is further electrically connected to the thin film transistor TFT via a conductive pattern located in the second source-drain conductive layer 210; the second anode L12 is electrically connected to the second source-drain conductive layer 210 via a connection line located in the connection layer 212, and is further electrically connected to the thin film transistor TFT via the conductive pattern located in the second source-drain conductive layer 210.

The encapsulation layer 4 may include a first encapsulation sub-layer 401, a second encapsulation sub-layer 402 and a third encapsulation sub-layer 403 that are sequentially stacked in a direction away from the substrate 1. For example, a material of the first encapsulation sub-layer 401 and a material of the third encapsulation sub-layer 403 each include an inorganic material, and a material of the second encapsulation sub-layer 402 includes an organic material. The first encapsulation sub-layer 401 and the third encapsulation sub-layer 403 each have an effect of blocking moisture and oxygen, and the second encapsulation sub-layer 402 has a certain flexibility and an effect of absorbing moisture.

An arrangement of film layers of the display panel 200 is described above, and a circuit structure of the pixel circuit 21 of the display panel 200 and a layout structure of the display panel 200 will be described below.

The circuit structure of the pixel circuit 21 may be implemented in various manners, such as a structure of “7T1C” (that is, the pixel circuit 21 includes 7 thin film transistors TFT and 1 capacitance structure Cst), “3T2C” (that is, the pixel circuit 21 includes 3 thin film transistors TFT and 2 capacitance structures Cst) or the like, which is not limited in the embodiments of the present disclosure.

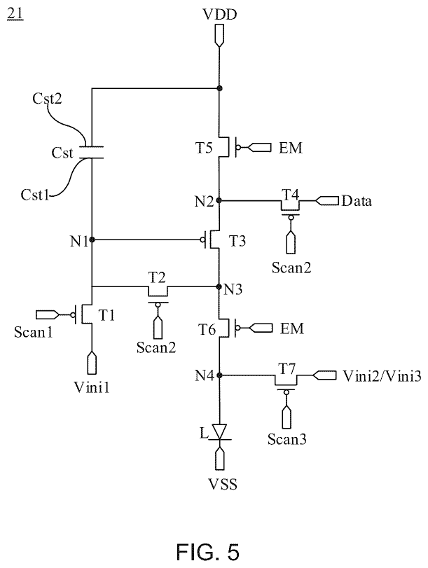

FIG. 5 shows an equivalent circuit diagram of the pixel circuit 21. As shown in FIG. 5, in some embodiments, the pixel circuit 21 has a circuit structure of “7T1C”.

Referring to FIG. 5, the pixel circuit 21 includes a plurality of thin film transistors TFT, which are respectively a first transistor T1, a second transistor 12, a third transistor T3, a fourth transistor T4, a fifth transistor T5, a sixth transistor T6 and a seventh transistor T7, and a capacitance structure Cst.

The first transistor T1 is a reset transistor used for resetting a first node N1, the second transistor T2 is a diode connection transistor, the third transistor T3 is a driving transistor, the fourth transistor T4 is a data writing transistor, the fifth transistor T5 and the sixth transistor T6 are each a light-emitting control transistor, and the seventh transistor T7 is another reset transistor used for resetting a light-emitting device.

It will be noted that in the circuit as shown in FIG. 5, the nodes N1, N2, N3 and N4 do not represent components that actually exist, but represent junction points of relevant electrical connections in the circuit diagram. That is, these nodes are nodes equivalent to the junction points of the relevant electrical connections in the circuit diagram.

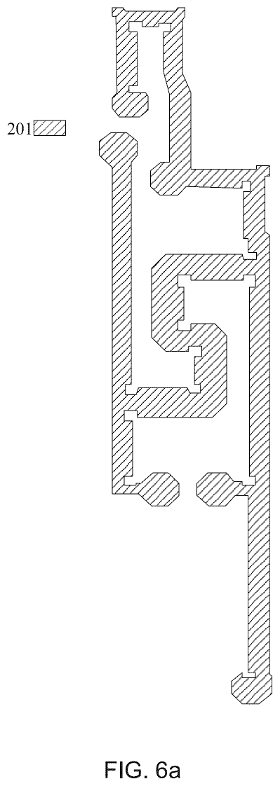

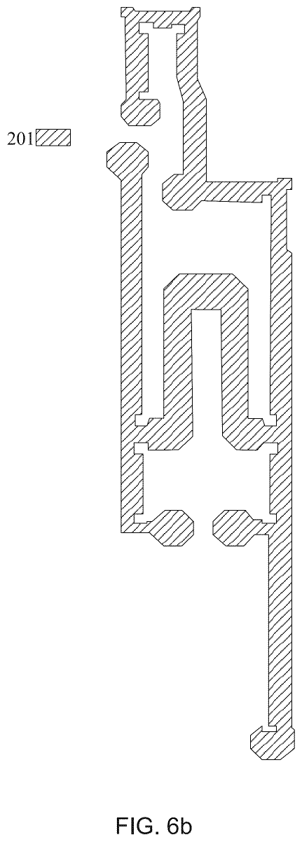

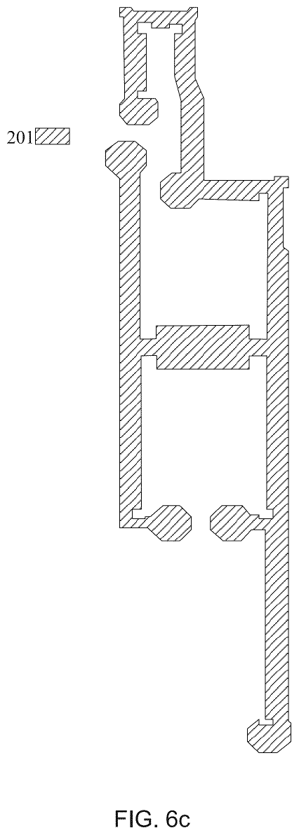

As shown in FIGS. 6a to 19, the display panel 200 includes film layers that each have pattern(s) and are arranged in a stack, so as to constitute all thin film transistors TFT and the light-emitting device L corresponding to the pixel circuit 21 that are in the equivalent circuit as shown in FIG. 5.

As shown in FIG. 6a, the active layer 201 is formed first. Optionally, a material of the active layer 201 includes low temperature poly-silicon.

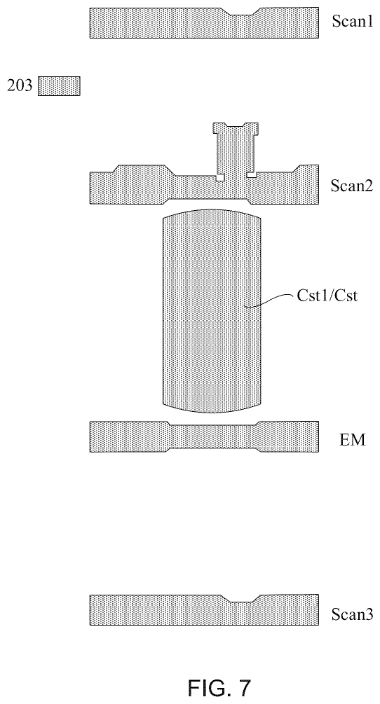

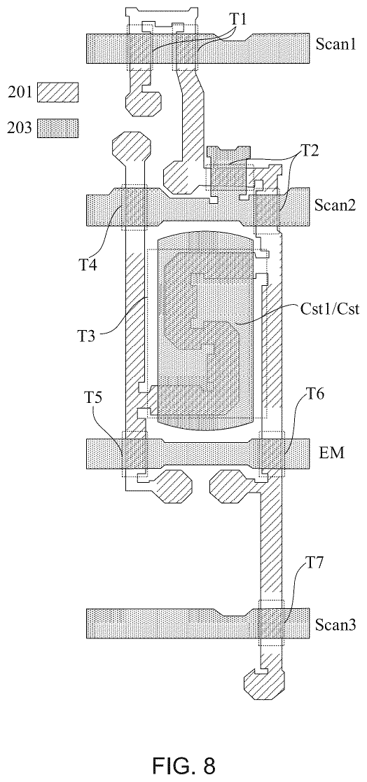

As shown in FIGS. 7 and 8, the first gate conductive layer 203 is formed on the active layer 201. Overlapping portions of the first gate conductive layer 203 and the active layer 201 constitute the first transistor T1, the second transistor T2, the third transistor T3, the fourth transistor T4, the fifth transistor T5, the sixth transistor T6 and the seventh transistor T7, respectively.

As shown in FIGS. 6a and 8, the third transistor T3 serves as the driving transistor. An active layer pattern of the third transistor T3 is substantially in a shape of “S”, and has a relatively long channel and a relatively small width-to-length ratio, which is conducive to reducing a current fluctuation and improving a stability of an output current.

Optionally, as shown in FIG. 6b, the active layer pattern of the third transistor T3 may be substantially in a shape of a Chinese character “ [symbol] ”. Alternatively, as shown in FIG. 6c, the active layer pattern of the third transistor T3 may be substantially in a shape of a transverse straight line.

For example, the active layer 201 and the first gate conductive layer 203 are provided with the first gate insulating layer 202 (with reference to FIG. 4) therebetween.

Referring to FIG. 7, the first gate conductive layer 203 includes an enable signal line EM, a first scan signal line Scan1, a second scan signal line Scan2, a third scan signal line Scan3, and a lower plate (i.e., the first plate) Cst1 of the capacitance structure Cst.

Portions of the enable signal line EM overlapping with the active layer 201 respectively constitute a gate of the fifth transistor T5 and a gate of the sixth transistor T6, thereby providing an enable signal for the fifth transistor T5 and the sixth transistor T6,

Portions of the first scan signal line Scan1 overlapping with the active layer 201 constitute gates of the first transistor T1, thereby providing a reset signal for the first transistor T1. As shown in FIG. 8, the first transistor T1 is a double-gate transistor.

Portions of the second scan signal line Scan2 overlapping with the active layer 201 respectively constitute gates of the second transistor T2 and a gate of the fourth transistor T4, thereby providing a second scan signal for the second transistor T2 and the fourth transistor T4. As shown in FIG. 8, the second transistor T2 is a double-gate transistor.

A portion of the third scan signal line Scan3 overlapping with the active layer 201 constitutes a gate of the seventh transistor T7, thereby providing a third scan signal for the seventh transistor T7.

It is worth noting that, referring to FIG. 8, a third scan signal line Scan3 of a pixel circuit 21 in a previous row also serves as a first scan signal line Scan1 electrically connected to a first transistor T1 of a pixel circuit 21 in a current row actually. The first scan signal line Scan1 transmits a third scan signal, serving as a reset signal of the pixel circuit 21 in the current row, of the pixel circuit 21 in the previous row. A third scan signal transmitted by the third scan signal line Scan3 serves as a reset signal of a pixel circuit 21 in a next row.

Optionally, the scan signals respectively transmitted by the second scan signal line Scan2 and the third scan signal line Scan3 are the same. That is, the second scan signal and the third scan signal are the same.

An overlapping portion of the lower plate Cst1 of the capacitance structure Cst and the active layer 201 constitutes the third transistor T3. That is, the lower plate Cst1 of the capacitance structure Cst also serves as a gate of the third transistor T3.

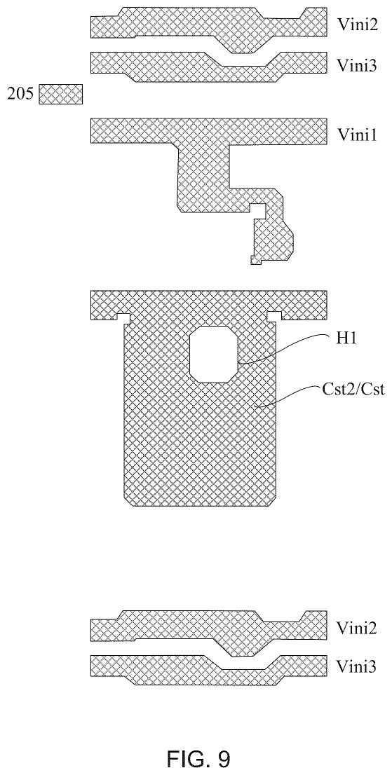

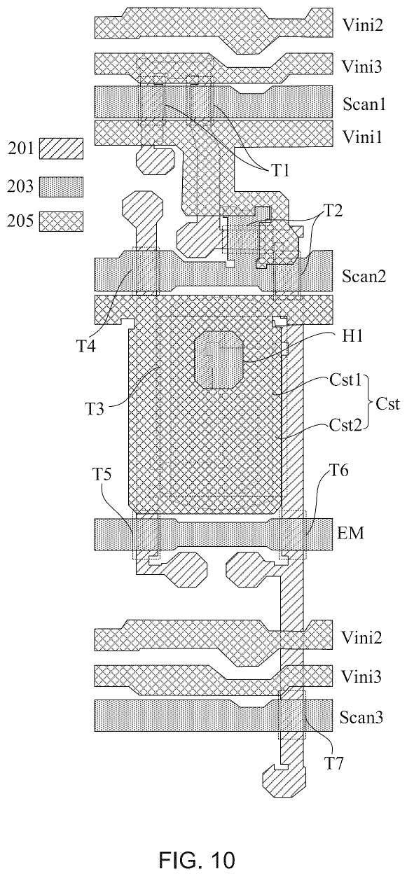

As shown in FIGS. 9 and 10, the second gate conductive layer 205 is formed on the first gate conductive layer 203.

Optionally, the second gate insulating layer 204 (with reference to FIG. 4) is disposed between the first gate conductive layer 203 and the second gate conductive layer 205.

Referring to FIG. 9, the second gate conductive layer 205 includes a first initialization signal line Vini1, second initialization signal lines Vini2 and an upper plate (i.e., the second plate) Cst2 of the capacitance structure Cst.

The first initialization signal line Vini1 is configured to be electrically connected to the first transistor T1 to provide a first initialization signal for the first transistor T1.

A second initialization signal line Vini2 is configured to be electrically connected to the seventh transistor T7 to provide a second initialization signal for the seventh transistor T7.

The upper plate Cst2 of the capacitance structure Cst and the lower plate Cst1 of the capacitance structure Cst in the first gate conductive layer 203 constitute the capacitance structure Cst. The upper plate Cst2 of the capacitance structure Cst is provided with a first via hole H1 therein, so as to facilitate exposing a portion of the first gate conductive layer 203 corresponding to the third transistor T3.

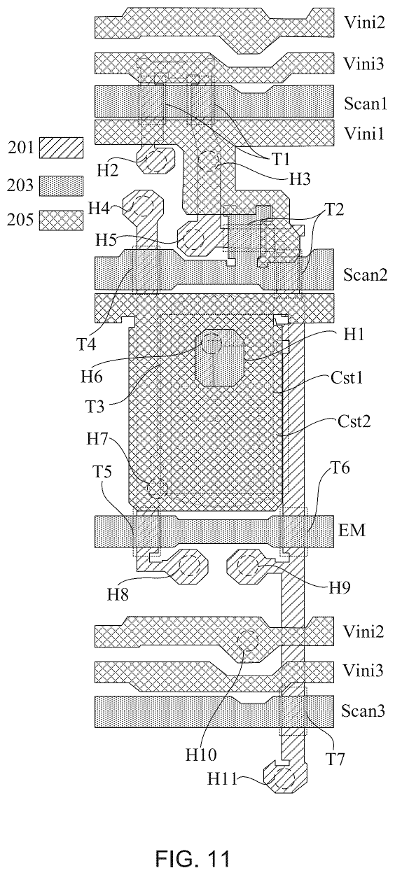

The interlayer dielectric layer 206 is formed on the second gate conductive layer 205, and a plurality of via holes (i.e., a second via hole H2 to an eleventh via hole H11 as shown in FIG. 11) are formed in the interlayer dielectric layer 206.

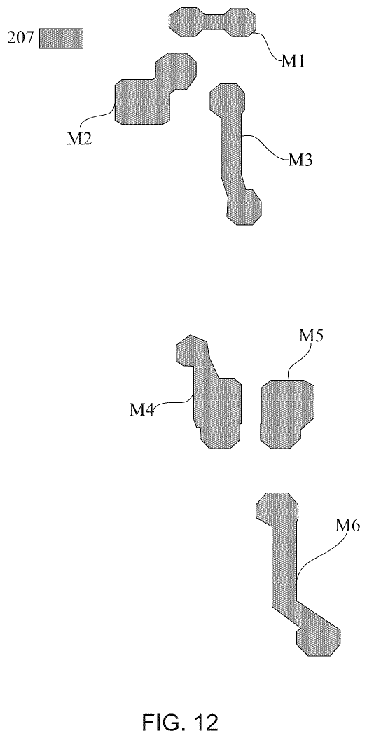

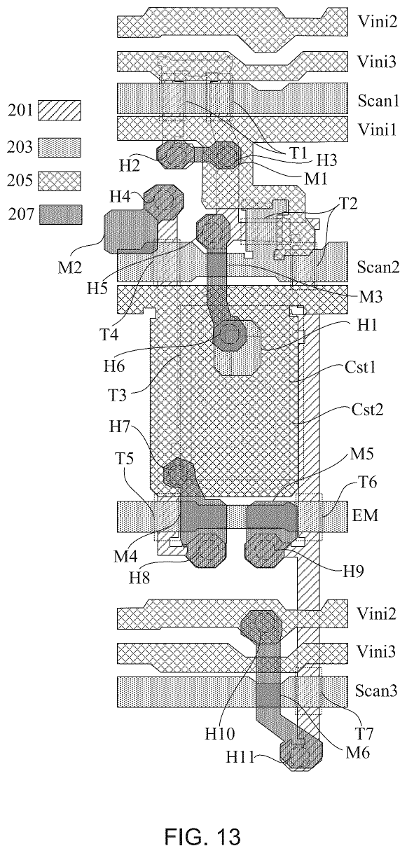

The first source-drain conductive layer 207 is formed on the interlayer dielectric layer 206, as shown in FIGS. 12 and 13, the first source-drain conductive layer 207 includes a plurality of conductive patterns (i.e., a first conductive pattern M1 to a sixth conductive pattern M6).

As shown in FIG. 13, one end of the first conductive pattern M1 is electrically connected to a first electrode of the first transistor T1 through the second via hole H2, and the other end is electrically connected to the first initialization signal line Vini1 through the third via hole H3, thereby achieving an electrical connection between the first initialization signal line Vini1 and the first transistor T1.

The second conductive pattern M2 is electrically connected to a first electrode of the fourth transistor T4 through the fourth via hole H4.

One end of the third conductive pattern M3 is electrically connected to the lower plate Cst1 of the capacitance structure Cst (i.e., the gate R1 of the third transistor T3) through the sixth via hole H6 and the first via hole H1, and the other end of the third conductive pattern M3 is electrically connected to a second electrode of the first transistor T1 and a second electrode of the second transistor T2 through the fifth via hole H5, thereby enabling the first transistor T1 and the second transistor T2 to be electrically connected to the capacitance structure Cst and the third transistor T3.

One end of the fourth conductive pattern M4 is electrically connected to the upper plate Cst2 of the capacitance structure Cst through the seventh via hole H7, and the other end of the fourth conductive pattern M4 is electrically connected to a first electrode of the fifth transistor T5 through the eighth via hole H8, thereby achieving an electrical connection between the capacitance structure Cst and the fifth transistor T5.

The fifth conductive pattern M5 is electrically connected to a second electrode of the sixth transistor T6 and a second electrode of the seventh transistor T7 through the ninth via hole H9.

One end of the sixth conductive pattern M6 is electrically connected to the second initialization signal line Vini2 through the tenth via hole H10, and the other end of the sixth conductive pattern MS is electrically connected to a first electrode of the seventh transistor T7 through the eleventh via hole H11, thereby achieving an electrical connection between the seventh transistor T7 and the second initialization signal line Vini2.

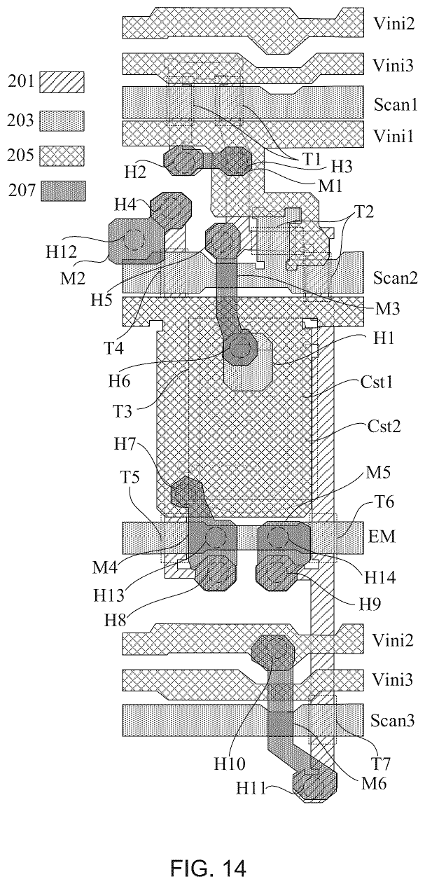

The first planarization layer 209 is formed on the first source-drain conductive layer 207, and a plurality of via holes (i.e., a twelfth via hole H12 to a fourteenth via hole H14 as shown in FIG. 14) are formed in the first planarization layer 209.

For example, the passivation layer 208 (with reference to FIG. 4) is disposed between the first source-drain conductive layer 207 and the first planarization layer 209.

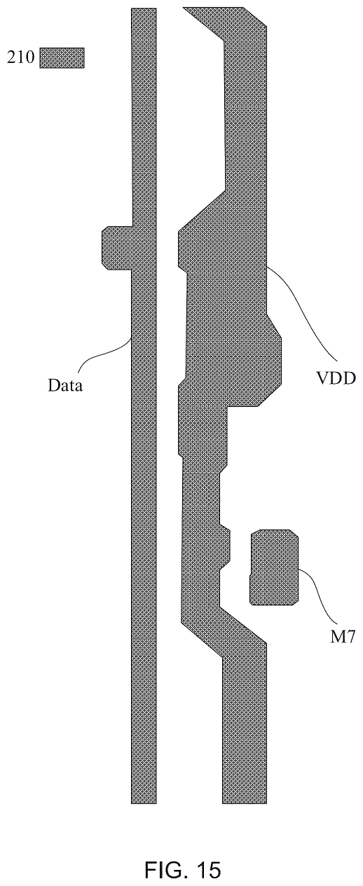

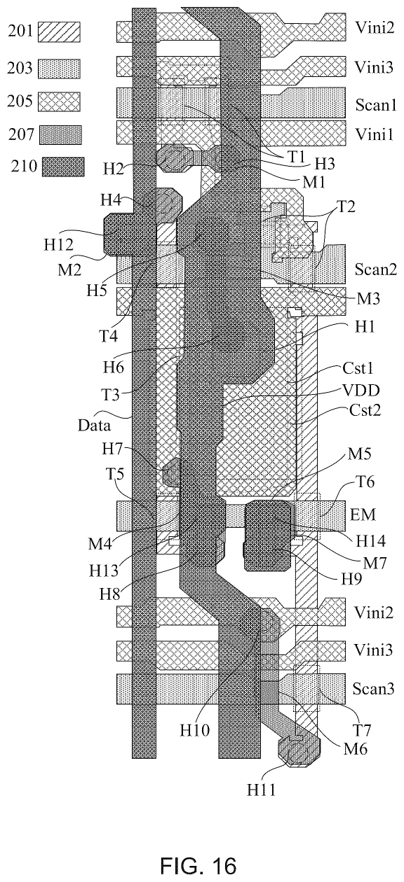

The second source-drain conductive layer 210 is formed on the first planarization layer 209, as shown in FIGS. 15 and 16, the second source-drain conductive layer 210 includes a data line Data, a power supply line VDD and a seventh conductive pattern M7.

The data line Data is electrically connected to the second conductive pattern M2 through the twelfth via hole H12, thereby achieving an electrical connection between the data line Data and the first electrode of the fourth transistor T4.

The power supply line VDD is electrically connected to a fourth connection pattern M4 through the thirteenth via hole H13, thereby enabling the power supply line VDD is electrically connected to the first electrode of the fifth transistor T5 and the upper plate Cst2 of the capacitance structure Cst through the fourth connection pattern M4.

The seventh conductive pattern M7 is electrically connected to a fifth connection pattern M5 through the fourteenth via hole H14, thereby achieving an electrical connection between the seventh conductive pattern M7 and the sixth transistor T6 and an electrical connection between the seventh conductive pattern M7 and the seventh transistor T7.

The second planarization layer 211 is formed on the second source-drain conductive layer 210.

It will be noted that the first electrode of each of all thin film transistor TFT (thin film transistors T1 to T7) used in the pixel circuit 21 is one of the source R2 and the drain 23 of the thin film transistor TFT, and the second electrode of the thin film transistor TFT is the other of the source R2 and the drain 23 of the thin film transistor TFT. Since the source R2 and the drain 23 of the thin film transistor TFT may be symmetrical in structure, the source R2 and the drain 23 thereof may be indistinguishable in structure. That is, the first electrode and the second electrode of the thin film transistor TFT in the embodiments of the present disclosure may be indistinguishable in structure. For example, in a case where the thin film transistor TFT is a P-type transistor, the first electrode of the transistor is the source R2, and the second electrode of the transistor is the drain R2. For another example, in a case where the thin film transistor TFT is an N-type transistor, the first electrode of the transistor is the drain R3, and the second electrode of the transistor is the source R1.

A layout structure of the pixel circuit 21 is constituted as above, and a layout structure of the light-emitting device L will be described below.

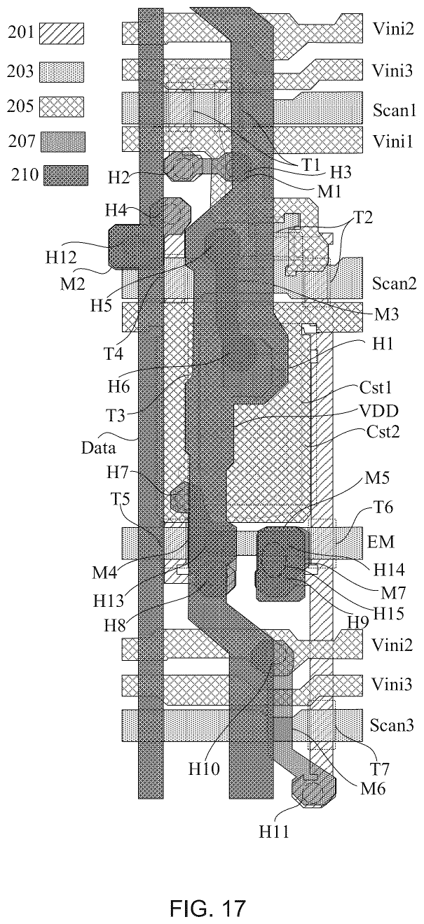

A fifteenth via hole H15 (as shown in FIG. 17) is provided in the second planarization layer 211.

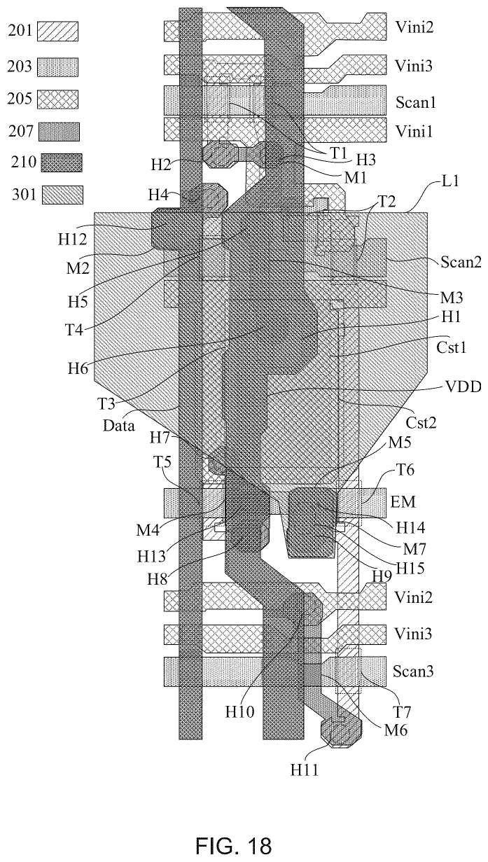

As shown in FIG. 18, the anode layer 301 is formed on the second planarization layer 211, and the anode layer 301 includes an anode L1.

The anode L1 is electrically connected to the seventh conductive pattern M7 through the fifteenth via hole H15, thereby achieving an electrical connection between the anode L1 and the second electrode of the sixth transistor T6 and an electrical connection between the anode L1 and the second electrode of the seventh transistor T7. As a result, an electrical connection between the pixel circuit 21 and the light-emitting device L is achieved, so that the pixel circuit 21 may be used for transmitting a voltage signal to the anode L1 of the light-emitting device L to drive the light-emitting device L to emit light.

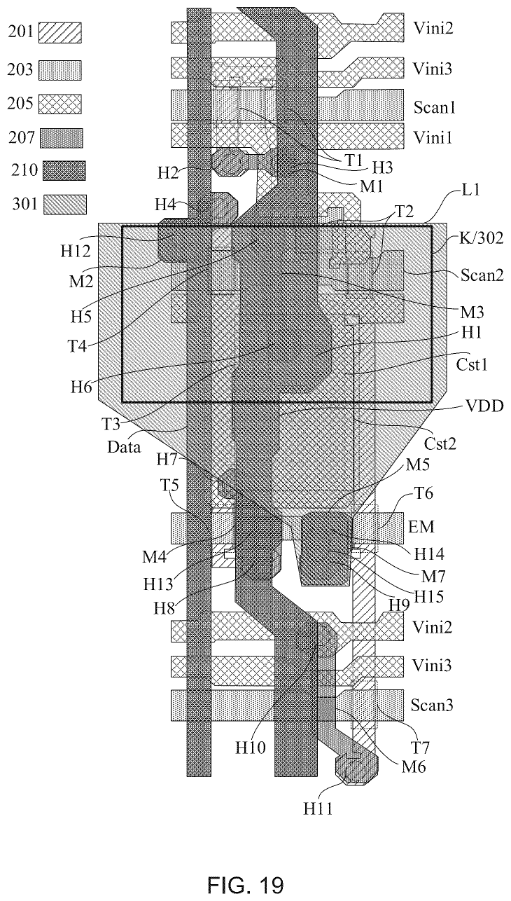

As shown in FIG. 19, the pixel definition layer 302 is formed on the anode layer 301, the openings K are disposed in the pixel definition layer 302, and an opening K corresponds to an anode L1,

Referring to FIG. 19, the opening K exposes at least a portion of the anode L1. Each opening K is used for defining an active light-emitting region of a light-emitting device L.

For example, the light-emitting functional layer 303 is formed on the pixel definition layer 302. The light-emitting pattern L3 of the light-emitting functional layer 303 is in contact with the anode L1 through the opening K.

For example, the cathode layer 304 is formed on the light-emitting functional layer 303.

The cathode layer 304 is of an integral structure and serves as the cathode L2, and the cathode L2 is configured to transmit the low-level voltage VSS.

Holes in the anode layer 301 and electrons in the cathode layer 304 are all transmitted, under driving of an electric field created by a high-level voltage transmitted by the anode L1 (i.e., from the pixel circuit 21) and the low-level voltage VSS of the cathode L2, to the light-emitting pattern L3 located in the opening K, and the holes and the electrons combine in the light-emitting pattern L3 to form excitons, so as to emit light.

In some embodiments, the connection layer 212 and the third planarization layer 213 are disposed between the pixel circuit layer 2 and the light-emitting device layer 3.

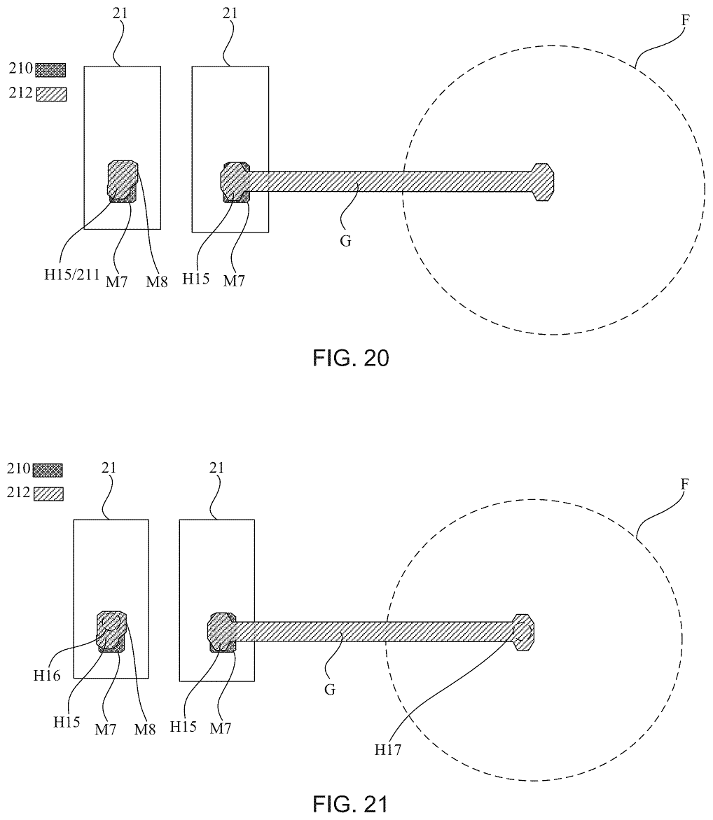

As shown in FIG. 20, the connection layer 212 is formed on the pixel circuit layer 2 (e.g., on the second planarization layer 211).

Referring to FIG. 20, the connection layer 212 is provided with a connection pattern M8 and at least one connection line G therein.

The connection pattern M8 is electrically connected to a pixel circuit 21 (e.g., a seventh conductive pattern M7 in the pixel circuit 21) corresponding to a light-emitting device L in the main display area A through the fifteenth via hole H15 in the second planarization layer 211, thereby achieving an electrical connection between the connection pattern M8 and each of a sixth transistor T6 and a seventh transistor T7 of the pixel circuit 21 corresponding to the light-emitting device L in the main display area A.

The connection line G is electrically connected to a pixel circuit 21 (e.g., a seventh conductive pattern M7 in the pixel circuit 21) corresponding to a light-emitting device L in the functional device area F through the fifteenth via hole H15, thereby achieving an electrical connection between the connection pattern M8 and each of a sixth transistor T6 and a seventh transistor T7 of the pixel circuit 21 corresponding to the light-emitting device L in the functional device area F.

The third planarization layer 213 is formed on the connection layer 212, and a sixteenth via hole H16 and a seventeenth via hole H17 (as shown in FIG. 21) are provided in the third planarization layer 213.

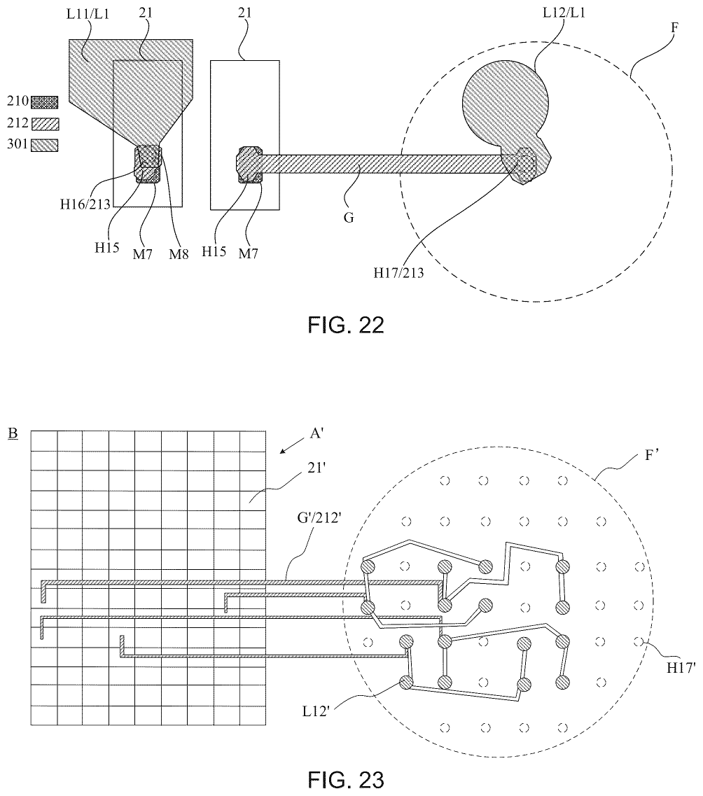

As shown in FIG. 22, the anode layer 301 is formed on the third planarization layer 213.

The anodes L1 are disposed in the anode layer 301 the anode L1 disposed in the main display area A is the first anode L11, and the anode L1 disposed in the functional device area F is the second anode L12.

The first anode L11 is electrically connected to the connection pattern M8 through the sixteenth via hole H16, which achieves an electrical connection between the first anode L11 and the pixel circuit 21 corresponding to the light-emitting device L in the main display area A, thereby achieving the light emission of the light-emitting device L in the main display area A.

The second anode L12 is electrically connected to the connection line G through the seventeenth via hole H17, which achieves an electrical connection between the second anode L12 and the pixel circuit 21 corresponding to the light-emitting device L in the functional device area F, thereby achieving the light emission of the light-emitting device L in the functional device area F.

As described above, in order to improve the light transmittance in the functional device area F, the pixel circuit 21 is disposed only in the main display area A, and the light-emitting device L in the functional device area F is electrically connected to the pixel circuit 21 located in the main display area A through the connection line G in the connection layer 212.

As shown in FIG. 23, in the related art, a design space of a connection layer 212′ used for arranging connection lines G′ is limited. Therefore, a connection line G′ is configured to be electrically connected to four second anodes L12′ in a functional device area F′, so as to use the relatively small number of connection lines G′ to drive the relatively large number of light-emitting devices L. As a result, the number of sub-pixels P each having a relatively high light transmittance (i.e., the number of sub-pixels P that are each non-overlapping with orthographic projections of respective pixel circuits 21′ on the substrate 1) is improved, and an area of the functional device area F′ is improved.

It has been found by the inventors of the present disclosure that a pixel circuit 21′ is electrically connected to four sub-pixels P in the functional device area F′, so that a driving current of each sub-pixel P is reduced by approximately three quarters compared with a driving current of a sub-pixel P in the main display area A′. As a result, in a light-emitting process, luminance in the functional device area F′ is accordingly lower than luminance in the main display area A′, and thus a contrast of light and dark at an interface of the main display area A′ and the functional device area F′ is obvious. Therefore, in a display process, a dark ring is prone to be observed at the interface of the two, which affects visual experience.

In addition, in the related art, an aperture ratio of the functional device area F′ is set to be approximately 0.5 times an aperture ratio of the main display area, so that the light transmittance in the functional device area F′ is improved.

It will be noted that the phrase “aperture ratio” refers to a proportion, in a unit area, of an area occupied by the opening K that is used for defining the light-emitting region and disposed on the pixel definition layer 302. In a case where a distribution density of sub-pixels P in the unit area is constant, the greater the area of the opening K, the greater the aperture ratio corresponding thereto. In a case where the area of the opening K is constant, the greater the distribution density of the sub-pixels P in the unit area, the greater the aperture ratio corresponding thereto.

It has been found by the inventors of the present disclosure that a proportion of a light-emitting region in the functional device area F′ is relatively small due to a relatively small aperture ratio, so that the luminance in the functional device area F′ is further reduced. As a result, the contrast of light and dark at the interface of the main display area A′ and the functional device area F′ is exacerbated.

In order to solve the above problems, some embodiments of the present disclosure provide a display panel 200.

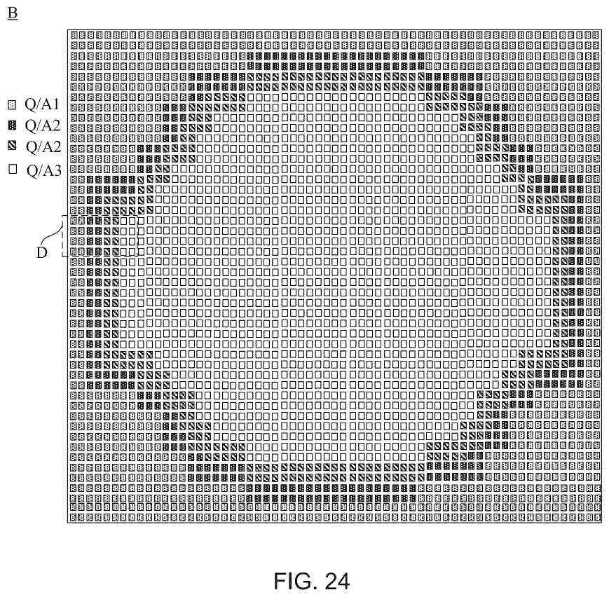

As shown in FIG. 24, the display panel 200 includes a first display region A1, at least one second display region A2 and a third display region A3; the at least one second display region A2 is located between the first display region A1 and the third display region A3, the first display region A1 at least partially surrounds the at least one second display region A2, and the at least one second display region A2 at least partially surrounds the third display region A3.

For example, referring to FIG. 24, a contour of the third display region A3 is substantially in a shape of a circle, the at least one second display region A2 is in a shape of a ring and is disposed around the third display region A3, and the first display region A1 surrounds the at least one second display region A2.

For example, the first display region A1 is located in the main display area A, and the at least one second display region A2 and the third display region A3 are located in the functional device area F.

For example, the first display region A1 and the at least one second display region A2 are located in the main display area A, and the third display region A3 is located in the functional device area F.

For example, the display pan& 200 includes a plurality of second display regions A2. For example, referring to FIG. 24, the display panel 200 includes two second display regions A2. For example, the first display region A1 and a second display region A2 that is closer to the first display region A1 are located in the main display area A, and the third display region A3 and a second display region A2 that is farther away from the first display region A1 are located in the functional device area F.

In the embodiments of the present disclosure, the display pan& 200 includes a substrate 1, an anode layer 301 and a pixel definition layer 302. The anode layer 301 is disposed on the substrate 1, and the anode layer 301 includes a plurality of anodes L1. The pixel definition layer 302 is disposed on a side of the anode layer 301 away from the substrate 1, the pixel definition layer 302 is provided with a plurality of openings K therein, and an opening K exposes at least a portion of an anode L1 corresponding thereto.

The first display region A1, the at least one second display region A2 and the third display region A3 are each provided with openings K of the plurality of openings K, and aperture ratios of the first display region A1, the at least one second display region A2 and the third display region A3 sequentially decrease.

For example, a ratio of the aperture ratios of the first display region A1, the at least one second display region A2 and the third display region A3 is in a range from 1:0.6:0.5 to 1:0.9:0.5, such as 1:0.85:0.5, 1:0.8:0.5, 1:0.75:0.5, 1:0.725:0.5, 1:0.7:0.5 or 1:0.6:0.5.

The aperture ratios of the first display region A1, the at least one second display region A2 and the third display region A3 sequentially decrease. That is, a transition region is provided at the interface of the main display area A and the functional device area F. Therefore, a gradual change of aperture ratios from the main display area A to the functional device area F is achieved, which prevents the contrast of light and dark between the luminance in the main display area A and the luminance in the functional device area F from being obvious due to a sudden decrease of aperture ratios between the main display area A and the functional device area F, so that the dark ring observed at the interface of the two is eliminated. As a result, a display effect of the display apparatus 100 is improved.

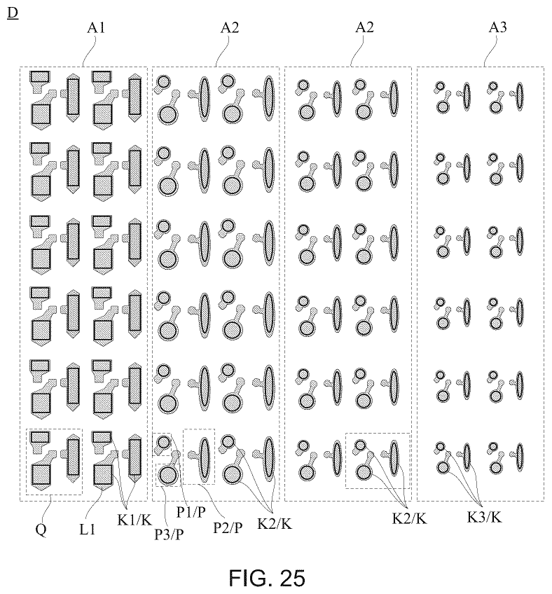

As shown in FIG. 25, in some embodiments, the display panel 200 includes a plurality of second display regions A2 that are sequentially nested, and aperture ratios of the plurality of second display regions A2 sequentially decrease in a direction from the first display region A1 to the third display region A3.

It will be noted that “the direction from the first display region A1 to the third display region A3” includes a direction from any position of the first display region A1 to a geometrical center of the third display region A3. For example, in a case where the third display region A3 is substantially in a shape of a circle, the geometric center of the third display region A3 is a center of the circle, and directions each pointing to the center of the circle along a radius of the circle are all within a protection scope of “the direction from the first display region A1 to the third display region A3”.

The plurality of second display regions A2 are provided, and the aperture ratios of the plurality of second display regions A2 are set to sequentially decrease, so that the number of transition regions at the interface of the main display area A and the functional device area F is improved. As a result, a transition from the luminance in the main display area A to the luminance in the functional device area F is enabled to be more even, which further eliminates the dark ring observed at the interface of the two, thereby improving the display effect of the display apparatus 100,

As shown in FIG. 25, in some embodiments, the display panel 200 includes a plurality of sub-pixels P capable of emitting light of a plurality of colors. For example, the display panel 200 includes first sub-pixels P1, second sub-pixels P2 and third sub-pixels P3. For example, the first sub-pixels P1 are each able to emit light of a red color, the second sub-pixels P2 are each able to emit light of a blue color, and the third sub-pixels P3 are each able to emit light of a green color.

An opening K is used for defining a light-emitting region of a sub-pixel P.

The plurality of openings K of the pixel definition layer 302 include first openings K1, second openings K2 and third openings K3, the first openings K1 are disposed in the first display region A1, the second openings K2 are disposed in the at least one second display region A2, and the third openings K3 are disposed in the third display region A3.

Areas of orthogonal projections, on the substrate 1, of a first opening K1, a second opening K2 and a third opening K3 that are corresponding to sub-pixels P emitting light of a same color sequentially decrease. For example, in the first sub-pixels P1 that are each able to emit light of the red color, an area of an orthogonal projection, on the substrate 1, of an opening K of a first sub-pixel P1 located in the first display region A1 is greater than an area of an orthogonal projection, on the substrate 1, of an opening K of a first sub-pixel P1 located in the second display region A2; and the area of the orthogonal projection, on the substrate 1, of the opening K of the first sub-pixel P1 located in the second display region A2 is greater than an area of an orthogonal projection, on the substrate 1, of an opening K of a first sub-pixel P1 located in the third display region A3.

For example, a ratio of the areas of the orthogonal projections, on the substrate 1, of the first opening K1, the second opening K2 and the third opening K3 that are corresponding to the sub-pixels P emitting the light of the same color is in a range from 1:0.6:0.5 to 1:0.9:0.5, such as 1:0.9:0.5, 1:0.85:0.5, 1:0.825:0.5, 1:0.75:0.5, 1:0.7:0.5 or 1:0.6:0.5.

The areas of the orthogonal projections, on the substrate 1, of the first opening K1, the second opening K2 and the third opening K3 that are corresponding to the sub-pixels P emitting the light of the same color sequentially decrease. In this way, a sequential decrease of the aperture ratios of the first display region A1, the at least one second display region A2 and the third display region A3 is achieved, so that the contrast of light and dark between the luminance in the main display area A and the luminance in the functional device area F is prevented from being obvious due to the sudden decrease of the aperture ratios between the main display area A and the functional device area F. As a result, the dark ring observed at the interface of the two is eliminated, thereby improving the display effect of the display apparatus 100.

For example, sizes of second openings K2 corresponding to sub-pixels P emitting light of a same color in the plurality of second display regions A2 are substantially equal.

As shown in FIG. 25, for example, the display panel 200 includes the plurality of second display regions A2 that are sequentially nested. In the second openings K2 disposed in the plurality of second display regions A2, areas of orthogonal projections, on the substrate 1, of second openings K2 corresponding to sub-pixels P emitting the light of a same color sequentially decrease in the direction from the first display region A1 to the third display region A3.

For example, referring to FIG. 25, in the two second display regions A2, an area of an orthogonal projection, on the substrate 1, of a second opening K2 corresponding to a sub-pixel P in a second display region A2 closer to the first display region A1 is greater than an area of an orthogonal projection, on the substrate 1, of a second opening K2 corresponding to a sub-pixel P that emits the light of the same color, as the sub-pixel P in the second display region A2 closer to the first display region A1, in a second display region A2 closer to the third display region A3.

For example, in openings K corresponding to the second sub-pixels P2 each emitting the light of the blue color, a ratio of areas of the first opening K1, the second opening K2 disposed in the second display region A2 closer to the first display region A1, the second opening K2 disposed in the second display region A2 farther away from the first display region A1 and the third opening K3 is in a range from 1:0.8:0.6:0.5 to 1:0.9:0.8:0.5, such as 1:0.8:0.6:0.5, 1:0.825:0.6:0.5, 1:0.825:0.65:0.5, 1:0.85:0.7:0.5 or 1:0.875:0.7:0.5.

The plurality of second display regions A2 are provided, and the areas of the orthogonal projections, on the substrate 1, of the second openings K2 corresponding to the sub-pixels P that emit the light of the same color and are respectively in different second display regions A2 sequentially decrease in the direction from the first display region A1 to the third display region A3. In this way, a transition of an aperture ratio at the interface of the main display area A and the functional device area F is caused to be more even, which further eliminates the dark ring observed at the interface of the two, thereby improving the display effect of the display apparatus 100.

As shown in FIG. 25, in some embodiments, the display panel 200 includes a plurality of display regions, and the plurality of display regions include the first display region A1, the at least one second display region A2 and the third display region A3. In the plurality of display regions, a difference between areas of orthogonal projections, on the substrate 1, of openings K that are respectively located in every two adjacent display regions and correspond to sub-pixels P emitting light of a same color is ΔS, and each ΔS has an approximately equal value.

For example, a difference between an area of an opening K corresponding to a sub-pixel (e.g., a first sub-pixel P1) emitting the light of the red color in the first display region A1 and an area of an opening K corresponding to a sub-pixel P emitting the light of the red color in the second display region A2 adjacent to the first display region A1 is ΔS1; a difference between an area of an opening K corresponding to a sub-pixel P emitting the light of the red color in the third display region A3 and an area of an opening K corresponding to a sub-pixel P emitting the light of the red color in the second display region A2 adjacent to the third display region A3 is ΔS2; a difference between areas of openings K, that are respectively located in the two adjacent second display regions A2, emitting the light of the red color is ΔS3, magnitudes of ΔS1, ΔS2 and ΔS3 are approximately equal.

Each ΔS has an approximately equal value, so that the aperture ratios decrease in uniformity in the direction from the first display region A1 to the third display region A3. As a result, the contrast of light and dark between luminance in the two adjacent display regions is further weakened, which ameliorates the generation of the dark ring, thereby improving the display effect of the display apparatus 100.

In some embodiments, a distribution density of the openings K in the first display region A1, a distribution density of the openings K in the at least one second display region A2 and a distribution density of the openings K in the third display region A3 sequentially decrease.

As shown in FIG, 26, a distribution density of pixels Q in the first display region A1, a distribution density of pixels Q in the at least one second display region A2 and a distribution density of pixels Q in the third display region A3 sequentially decrease, so that the distribution density of the openings K in the first display region A1 the distribution density of the openings K in the at least one second display region A2 and the distribution density of the openings K in the third display region A3 sequentially decrease.

The distribution densities of the respective openings K sequentially decrease, so that the sequential decrease of the aperture ratios of the first display region A1, the at least one second display region A2 and the third display region A3 is achieved. As a result, the obviousness, due to the sudden decrease of the aperture ratios between the main display area A and the functional device area F, of the contrast of light and dark between the luminance in the main display area A and the luminance in the functional device area F is avoided, which eliminates the dark ring observed at the interface of the two, thereby improving the display effect of the display apparatus 100.

For example, distribution densities of the second openings K2 respectively disposed in the plurality of second display regions A2 are approximately equal.

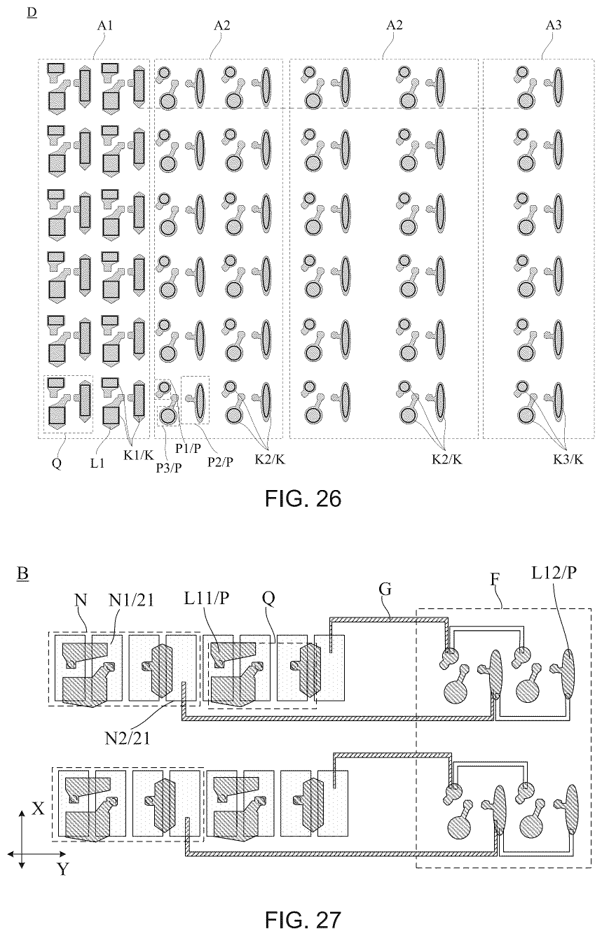

As shown in FIG. 26, for example, the display panel 200 includes the plurality of second display regions A2 that are sequentially nested. Distribution densities of the second openings K2 respectively disposed in the plurality of second display regions A2 sequentially decrease in the direction from the first display region A1 to the third display region A3.

For example, referring to FIG. 26, in the two second display regions A2, a distribution density of second openings K2 in the second display region A2 closer to the first display region A1 is greater than a distribution density of second openings K2 in the second display region A2 closer to the third display region A3.

The plurality of second display regions A2 are provided, and the distribution densities of the second openings K2 respectively disposed in the different second display regions A2 are enabled to sequentially decrease, so that the transition of the aperture ratio at the interface of the main display area A and the functional device area F is more even. As a result, the dark ring observed at the interface of the two is further eliminated, thereby improving the display effect of the display apparatus 100.

As shown in FIG, 26, in some embodiments, the display panel 200 includes the plurality of display regions, and the plurality of display regions include the first display region A1, the at least one second display region A2 and the third display region A3. In the plurality of display regions, a difference between distribution densities of openings K that are respectively in every two adjacent display regions is ΔS′, and each ΔS′ has an approximately equal value.

Each ΔS′ has an approximately equal value, so that the aperture ratios decrease in uniformity in the direction from the first display region A1 to the third display region A3. As a result, the contrast of light and dark between the luminance in the two adjacent display regions is further weakened, which ameliorates the generation of the dark ring, thereby improving the display effect of the display apparatus 100.

As shown in FIGS. 25 and 26, in some embodiments, orthogonal projections, on the substrate 1, of the first openings K1 are each in a shape of a polygon; orthogonal projections, on the substrate 1, of the second openings K2 are each in a shape of a polygon, a circle or an ellipse; orthogonal projections, on the substrate 1, of the third openings K3 are each in a shape of a circle or an ellipse.

For example, an orthogonal projection, on the substrate 1, of an opening K located in the functional device area F is in a shape of a circle or an ellipse, which may reduce a reflection and a diffraction of light, thereby reducing an influence of the light on the functional device (e.g., a camera) in the functional device area F.

In some embodiments, the display panel 200 includes a plurality of pixel circuits 21 disposed between the substrate 1 and the anode layer 301, and a pixel circuit 21 is electrically connected to at least one anode L1.

Referring to FIG. 27, the plurality of pixel circuits 21 include a plurality of circuit units N, and a circuit unit N includes a plurality of first-type pixel circuits N1 and a second-type pixel circuit N2 that are sequentially arranged in a second direction Y.

For example, a circuit unit N corresponds to a position of a pixel Q in the main display area A.

For example, the circuit unit N includes three first-type pixel circuits N1, and the three first-type pixel circuits N1 are connected to respective light-emitting devices L emitting light of different colors.

The first-type pixel circuit N1 is electrically connected to at least one first anode L1, and the second-type pixel circuit N2 is electrically connected to the plurality of second anodes L2. That is, the first-type pixel circuit N1 is configured to be electrically connected to the light-emitting device(s) L in the main display area A, and the second-type pixel circuit N2 is configured to be electrically connected to the light-emitting devices L in the functional device area F.

For example, the first-type pixel circuit N1 is electrically connected to one first anode L11; alternatively, the first-type pixel circuit N1 is electrically connected to multiple first anodes L11. The second-type pixel circuit N2 is electrically connected to multiple second anodes L12. That is, the light-emitting devices L in the functional device area F may be driven by a same pixel circuit 21.

For example, the first-type pixel circuit N1 is electrically connected to the first anode L11 via a connection pattern M8, and the second-type pixel circuit N2 is electrically connected to the second anode L12 via a connection line G.

Due to the provision of the first-type pixel circuits N1 and the second-type pixel circuit N2, the pixel circuits 21 respectively corresponding to the sub-pixels P in the functional device area F are all arranged in the main display area A. In this way, a purpose of providing no pixel circuit 21 in the functional device area F is achieved, thereby avoiding the reduction of the light transmittance due to the blocking effect, on the light, of the metal film layers in the pixel circuit 21.

In some embodiments, in a plurality of display regions consisting of the first display region A1, the at least one second display region A2 and the third display region A3, a display region provided with pixel circuits 21 is a first transmittance region (i.e., the main display area A), and a display region provided with no pixel circuit 21 is a second transmittance region (i.e., the functional device area F). A light transmittance of the first transmittance region is less than a light transmittance of the second transmittance region.

For example, referring to FIG. 29, the plurality of pixel circuits 21 are disposed in the first display region A1. The first display region A1 is the first transmittance region. That is, the first display region A1 is located in the main display area A.

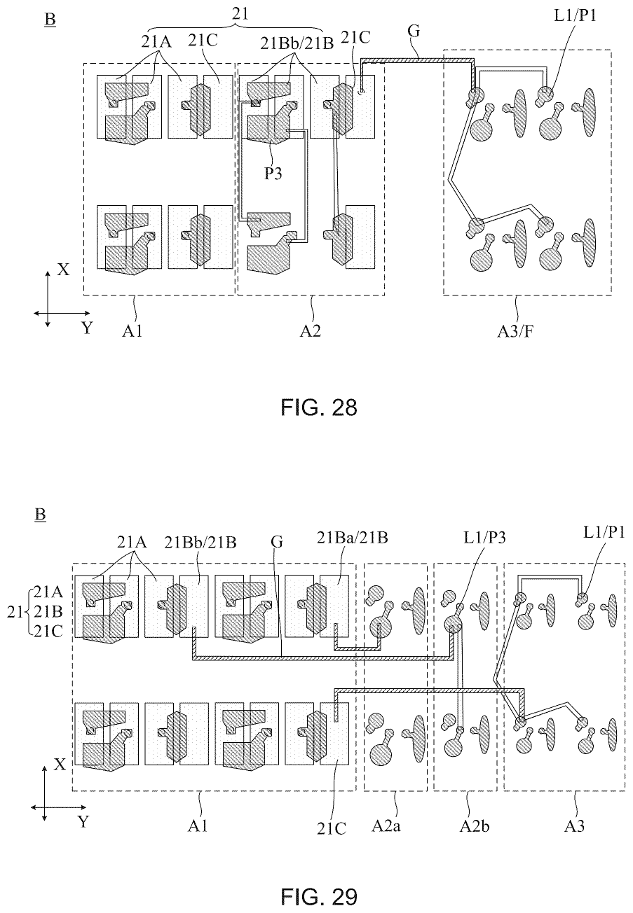

For example, referring to FIG. 28, the plurality of pixel circuits 21 are disposed in the first display region A1 and the plurality of second display regions A2. The first display region A1 and the plurality of second display regions A2 are each a first transmittance region. That is, the first display region A1 and the plurality of second display regions A2 are all located in the main display area A.

For example, the plurality of pixel circuits 21 are disposed in the first display region A1 and some of the second display regions A2. The first display region A1 and the some of the second display regions A2 are each the first transmittance region. That is, the first display region A1 and the some of the second display regions A2 are all located in the main display area A.

A second display region A2 provided with pixel circuits 21 is closer to the first display region A1 than a second display region A2 provided with no pixel circuit 21.

That is, the transition region disposed at the interface of the main display area A and the functional device area F may be located in the main display area A or the functional device area F; alternatively, the transition region may be located in both the main display area A and the functional device area F.

In some embodiments, the display pan& 200 further includes the plurality of pixel circuits 21 disposed between the substrate 1 and the anode layer 301, and a pixel circuit 21 is electrically connected to at least one anode L1.

Referring to FIGS. 28 and 29, the plurality of pixel circuits 21 include first pixel circuits 21A, second pixel circuits 21B and third pixel circuits 21C; the first pixel circuits 21A are each electrically connected to anode(s) L1 disposed in the first display region A1, the second pixel circuits 21B are each electrically connected to anodes L1 disposed in the at least one second display region A2, and the third pixel circuits 21C are each electrically connected to anodes L1 disposed in the third display region A3.

Referring to FIG. 29, the at least one second display region A2 includes a setting second display region A2b, and a second pixel circuit 21B electrically connected to anodes L1 disposed in the setting second display region A2b is a setting second pixel circuit 21Bb. The number of the anodes L1 electrically connected to the setting second pixel circuit 21Bb is greater than the number of anodes L1 electrically connected to a first pixel circuit 21A, and is less than the number of anodes L1 electrically connected to a third pixel circuit 21C. That is, the number of anodes L1 electrically connected to a pixel circuit 21 that is electrically connected to the anodes L1 in the first display region A1, the number of anodes L1 electrically connected to a pixel circuit 21 that is electrically connected to the anodes L1 in the second display region A2 and the number of anodes L1 electrically connected to a pixel circuit 21 that is electrically connected to the anodes L1 in the third display region A3 sequentially increases.

The plurality of pixel circuits 21 are provided, and the number of anodes L1 electrically connected to a pixel circuit 21 that is electrically connected to light-emitting device(s) L in the first display region A1, the number of anodes L1 electrically connected to a pixel circuit 21 that is electrically connected to light-emitting devices L in the second display region A2 and the number of anodes L1 electrically connected to a pixel circuit 21 that is electrically connected to light-emitting devices L in the third display region A3 sequentially increase. In this way, the transition from the luminance in the main display area A to the luminance in the functional device area F is more even, so that the dark ring observed at the interface of the two is further eliminated, and the display effect of the display apparatus 100 is improved.

As shown in FIG. 28, for example, the first pixel circuit 21A is electrically connected to one anode L1, the setting second pixel circuit 21Bb is electrically connected to two or three anodes L1, and the third pixel circuit 212C is electrically connected to at least three anodes L1.

For example, the first pixel circuit 21A is electrically connected to one anode L1 the setting second pixel circuit 21Bb is electrically connected to two anodes L1, and the third pixel circuit 212C is electrically connected to four anodes L1. For another example, the first pixel circuit 21A is electrically connected to one anode L1, a setting second pixel circuit 21Bb is electrically connected to two anodes L1, another setting second pixel circuit 21Bb is electrically connected to three anodes L1, and the third pixel circuit 212C is electrically connected to four anodes L1.

As shown in FIG. 29, for example, the at least one second display region A2 further includes a general second display region A2a; the general second display region A2a is located between the first display region A1 and the setting second display region A2b, and a second pixel circuit 21B electrically connected to anode(s) L1 disposed in the general second display region A2a is a general second pixel circuit 21Ba. The number of anodes L1 electrically connected to the general second pixel circuit 21Ba is equal to the number of anodes L1 electrically connected to the first pixel circuit 21A.

On the basis of the above embodiments, referring to FIGS. 28 and 29, in some embodiments, the display panel 200 includes the plurality of sub-pixels P capable of emitting light of a plurality of colors, and a sub-pixel P includes a single anode L1. Sub-pixels P to which anodes L1 electrically connected to a same setting second pixel circuit 21Bb respectively belong emit light of a same color; and/or sub-pixels P to which anodes L1 electrically connected to a same third pixel circuit 21C respectively belong emit light of a same color.

Referring to FIG. 28, for example, the setting second pixel circuit 21Bb is electrically connected to two anodes L1 respectively included in two sub-pixels P that are adjacent in a first direction X and emit the light of the same color. The third pixel circuit 21C is electrically connected to four anodes L1 respectively included in four sub-pixels P that are adjacent and emit the light of the same color, and the four anodes L1 are arranged in two columns in the first direction X, and are arranged in two rows in the second direction Y. The first direction X is perpendicular to the second direction V.

For example, referring to FIG. 28, the setting second pixel circuit 21Bb is electrically connected to two anodes L1 respectively included in two first sub-pixels P3 that are adjacent in the first direction X and emit the light of the green color. For example, referring to FIGS. 28 and 29, the third pixel circuit 21C is electrically connected to four anodes L1 respectively included in four first sub-pixels P1 that are adjacent and emit the light of the red color.

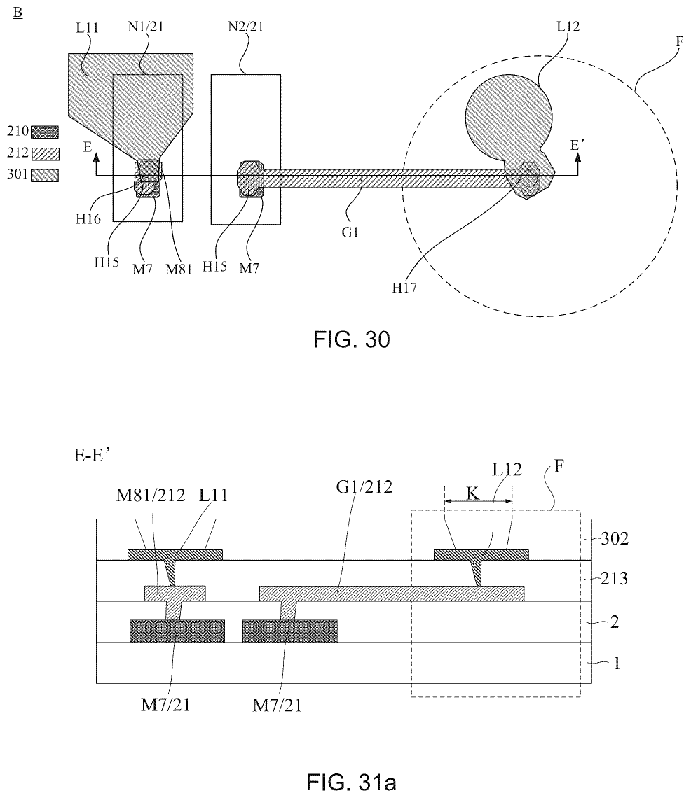

As shown in FIG. 4, in some embodiments, the display panel 200 further includes at least one connection layer 212 disposed between the plurality of pixel circuits 21 and the anode layer 301, and the at least one connection layer 212 includes a plurality of first connection patterns M81 and a plurality of first connection lines G1 (as shown in FIG. 30).

The plurality of anodes L1 include a plurality of first anodes L11 and a plurality of second anodes L12, the plurality of first anodes L11 are disposed in the first transmittance region (i.e., the main display area A), and the plurality of second anodes L12 are disposed in the second transmittance region (i.e., the functional device area F).

A first anode L11 is electrically connected to a respective pixel circuit 21 via at least one first connection pattern M81, and a second anode L12 is electrically connected to a respective pixel circuit 21 via at least one first connection line G1.

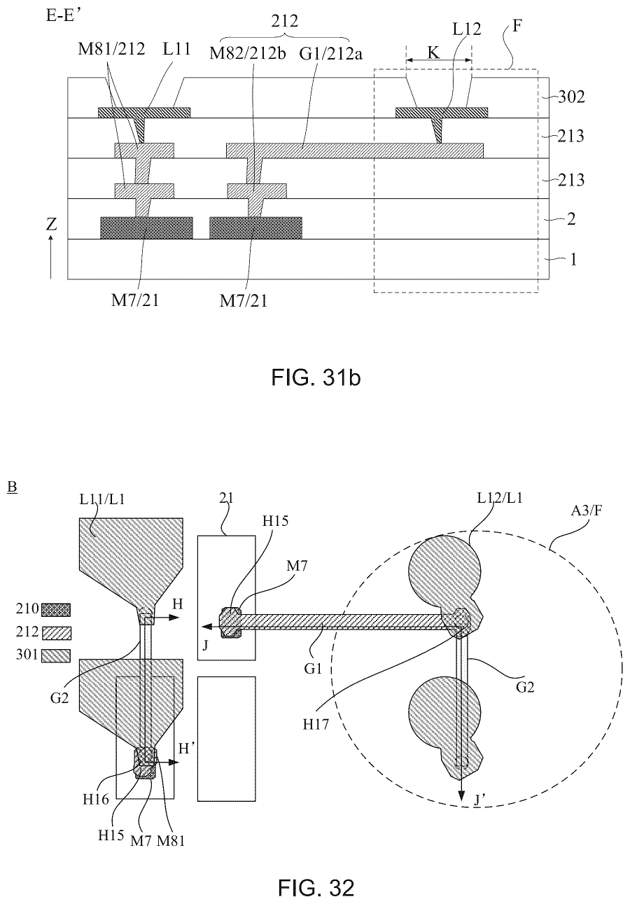

As shown in FIG. 31a, in some embodiments, the display panel 200 includes one connection layer 212. The first anode L11 is electrically connected to the respective pixel circuit 21 via the first connection pattern M81.

As shown in FIG. 31b, in some embodiments, the display panel 200 includes a plurality of connection layers 212. The first anode L11 is electrically connected to the respective pixel circuit 21 via multiple first connection patterns M81 of the plurality of first connection patterns, and the multiple first connection patterns M81 are respectively located in the plurality of connection layers 212; orthographic projections, on the substrate 1, of any two first connection patterns M81, that are adjacent in a direction parallel to a thickness direction Z of the substrate 1, of the multiple first connection patterns M81 at least partially overlap.

As shown in FIG. 31b, in some embodiments, the at least one connection layer 212 includes a first connection layer 212a and a second connection layer 212b, and the first connection layer 212a is farther away from the substrate 1 than the second connection layer 212b. A first connection line G1 used for being electrically connected to a second anode L12 and a respective pixel circuit 21 is located in the first connection layer 212a, The second connection layer 212b includes a second connection pattern M82, and the first connection line G1 is electrically connected to the respective pixel circuit 21 via the second conductive pattern M82.

For example, the display panel 200 includes a plurality of second connection layers 212b, and multiple second connection patterns M82 are respectively located in the plurality of second connection layers 212b; orthographic projections, on the substrate 1, of any two second connection patterns M82, that are adjacent in the direction parallel to the thickness direction of the substrate 1, of the multiple second connection patterns M82 at least partially overlap.

As shown in FIG. 32, in some embodiments, each of at least one pixel circuit 21 is electrically connected to at least two anodes L1 (e.g., at least two second anodes L12) of the plurality of anodes L1. The at least one connection layer 212 further includes a plurality of second connection lines G2, at least two anodes L1 electrically connected to a same pixel circuit 21 are electrically connected to each other via at least one second connection line G2, and one of the at least two anodes L1 electrically connected to the same pixel circuit 21 is electrically connected to a respective pixel circuit 21 via a first connection pattern M81 or a first connection line G1.

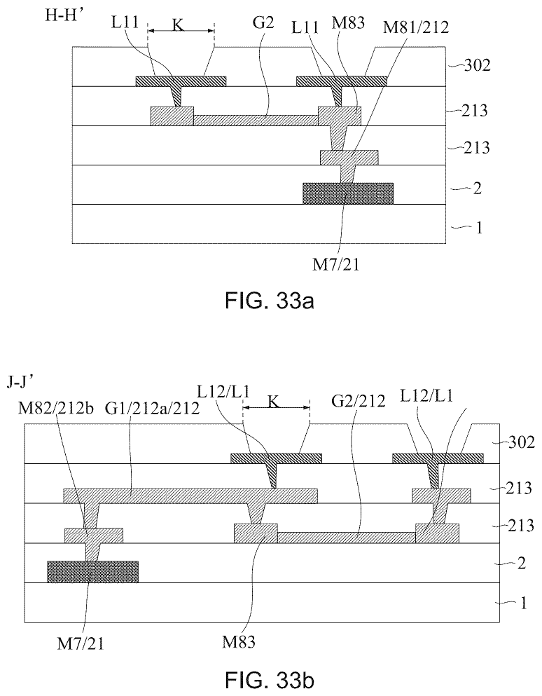

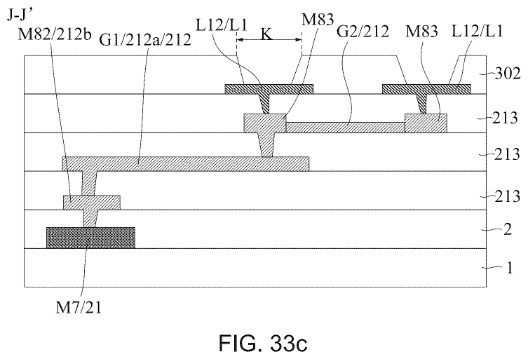

For example, referring to FIG. 33a, two first anodes L11 are electrically connected to each other via a second connection line G2, and the second connection line G2 is electrically connected to a pixel circuit 21, thereby achieving an electrical connection between the pixel circuit 21 and the two first anodes L11.

For example, referring to FIG. 33b, two second anodes L12 are electrically connected to each other via a second connection line G2, and the second connection line G2 is electrically connected to a pixel circuit 21, thereby achieving an electrical connection between the a pixel circuit 21 and the two second anodes L12.

In some embodiments, the display panel 200 includes the plurality of connection layers 212, and the plurality of first connection lines G1 and the plurality of second connection lines G2 are located in different connection layers 212.

For example, referring to FIG. 33b, a connection layer 212 where the first connection lines G1 and the first connection patterns M81 are located is farther away from the substrate 1 than another connection layer 212 where the second connection lines G2 are located.

For example, referring to FIG. 33c, a connection layer 212 where the first connection lines G1 and the first connection patterns M81 are located is closer to the substrate 1 than a connection layer 212 where the second connection lines G2 are located,

As shown in FIGS. 33b and 33c, in some embodiments, the at least one connection layer 212 further includes at least two third connection patterns M83, and the at least two anodes L1 electrically connected to the same pixel circuit 21 are each electrically connected to the at least two third connection patterns M83. The second connection line G2 used for being electrically connected to the at least two anodes L1 is disposed in a same connection layer as the at least two third connection patterns, and is electrically connected to the at least two third connection patterns M83.

For example, referring to FIGS. 31b, and 33a to 33c, in the above embodiments, any two connection layers 212 are provided with a third planarization layer 213 therebetween, and the connection layer 212 and the anode layer 301 are provided with another third planarization layer 213 therebetween.

Based on the above embodiments, some embodiments of the present disclosure provide a design of a film layer structure that may be combined with the above embodiments, thereby optimizing product performance of the display apparatus 100.

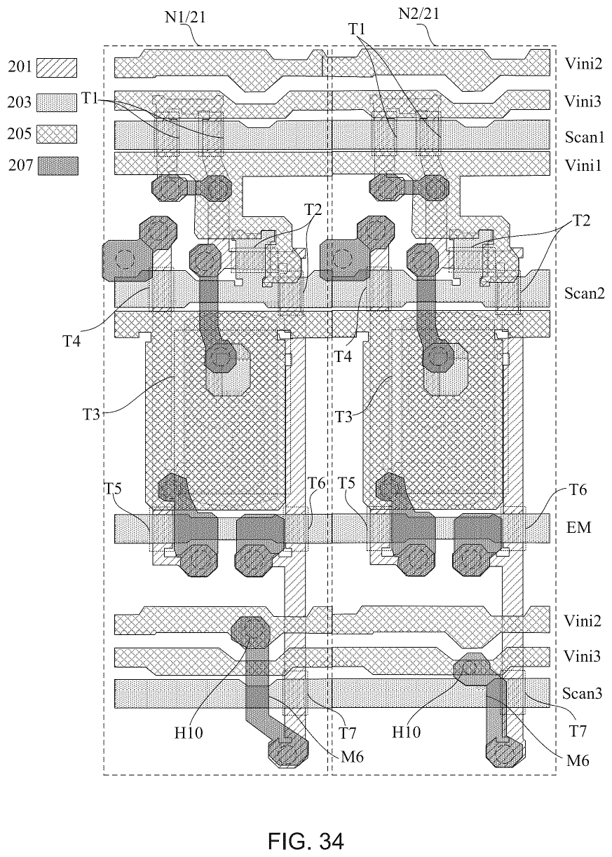

As shown in FIG. 34, in some embodiments, the display panel 200 further includes a second initialization signal line Vini2 and a third initialization signal line Vini3. In a same circuit unit N, the plurality of first-type pixel circuits N1 are electrically connected to the second initialization signal line Vini2, and the second-type pixel circuit N2 is electrically connected to the third initialization signal line Vini3. For example, a seventh transistor T7 of the first-type pixel circuit Ni is electrically connected to the second initialization signal line Vini2, and a seventh transistor T7 of the second-type pixel circuit N2 is electrically connected to the third initialization signal line Vini3.

The plurality of first-type pixel circuits N1 are electrically connected to the second initialization signal line Vini2, and the second-type pixel circuit N2 are electrically connected to the third initialization signal line Vini3. In this way, an initialization signal received by the light-emitting devices L located in the functional device area F is different from an initialization signal received by the light-emitting device(s) L located in the main display area A, so as to achieve the flexible control of the sub-pixels P in the functional device area F.

Referring to FIG. 4, in some embodiments, the display panel 200 includes the pixel circuit layer 2 disposed between the substrate 1 and the anode layer 301, and the pixel circuit layer 2 includes the active layer 201, the first gate conductive layer 203 and the second gate conductive layer 205 that are arranged in a stack in a third direction Z. The third direction Z is parallel to the thickness direction of the substrate 1, and is from the substrate 1 to the anode layer 301.

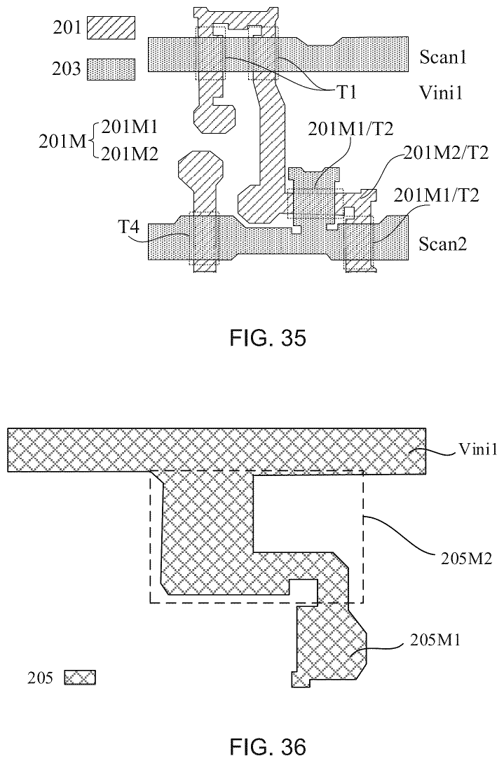

The pixel circuit layer 2 includes the plurality of pixel circuits 21, at least one pixel circuit 21 includes a compensation transistor (i.e., a second transistor T2 as described above); referring to FIG. 35, the compensation transistor includes a semiconductor pattern 201M disposed in the active layer 201 and two gates disposed in the first gate conductive layer 203.

Referring to FIG. 35, the semiconductor pattern 201M includes a first portion 201M1 and a second portion 201M2, an orthographic projection of the first portion 201M1 on the substrate 1 overlaps with orthographic projections of the two gates of the compensation transistor on the substrate 1, and an orthographic projection of the second portion 201M2 on the substrate 1 is located between the orthographic projections of the two gates of the compensation transistor on the substrate 1.

Referring to FIG. 36, the second gate conductive layer 205 includes a first initialization signal line Vini1, a light shielding pattern 205M1 and a connection portion 205M2, and the connection portion 205M2 is connected to the first initialization signal line Vini1 and the light shielding pattern 205M1.

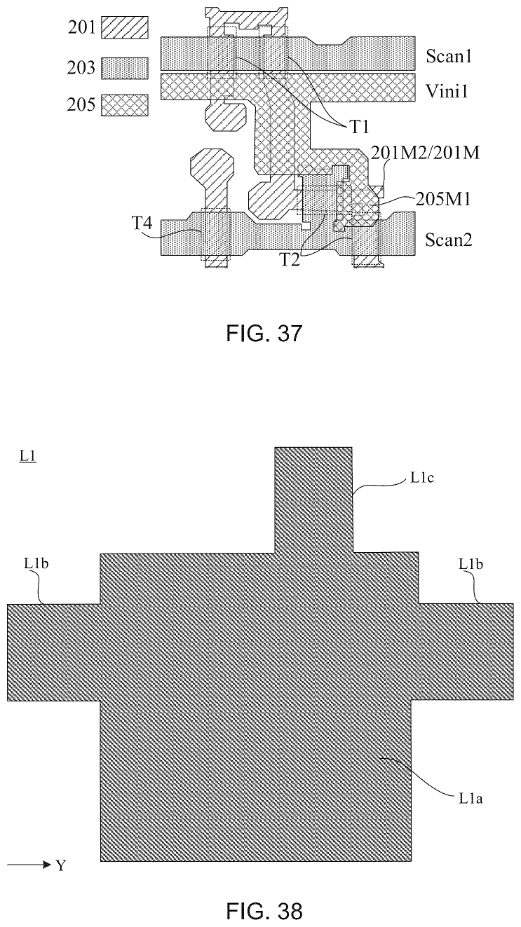

Referring to FIG. 37, an orthographic projection of the light shielding pattern 205M1 on the substrate 1 overlaps with the orthographic projection of the second portion 201M2 of the semiconductor pattern 201M on the substrate 1.

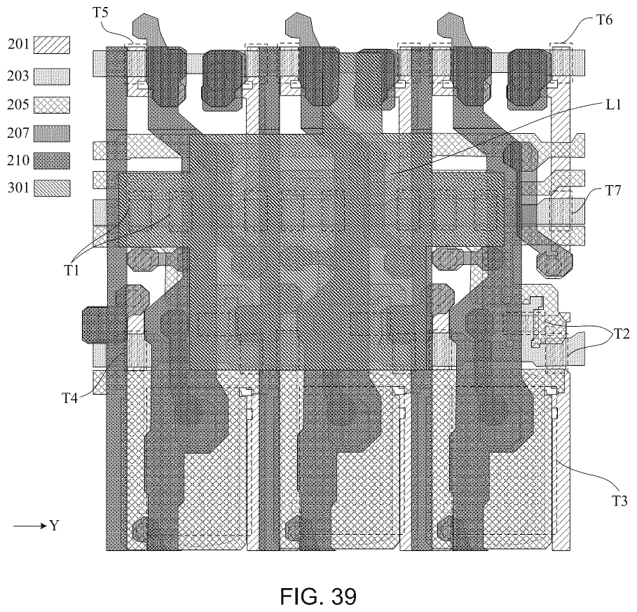

In some embodiments, the pixel circuit 21 further includes a first reset transistor (i.e., a first transistor T1), and as shown in FIG. 39, the first reset transistor includes other two gates disposed in the first gate conductive layer 203.

As shown in FIG. 38, each of at least one anode L1 includes a main body portion L1a, and two protruding portions L1b respectively located on two sides of the main body portion L1a in the second direction Y.

An orthographic projection, on the substrate 1, of the main body portion L1a of each of the at least one anode L1 is located between orthographic projections, on the substrate 1, of first reset transistors of two pixel circuits 21 arranged in the second direction Y; in a protruding portion L1b and a first reset transistor that are located on a same side of the main body portion L1a, the protruding portion L1b covers two gates of the first reset transistor.

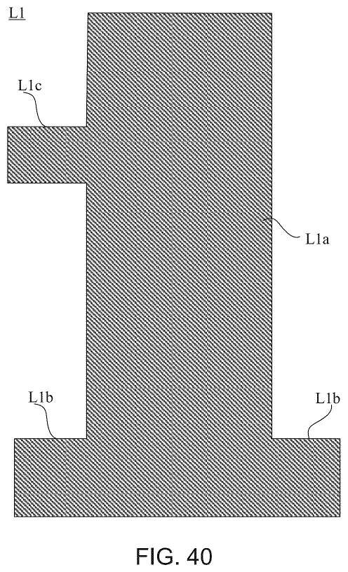

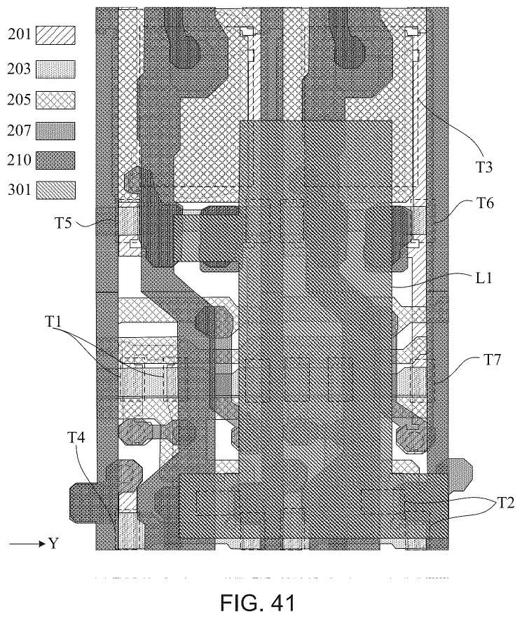

As shown in FIGS. 40 and 41, in some embodiments, the orthographic projection of the main body portion L1a on the substrate 1 is located between orthographic projections, on the substrate 1, of compensation transistors (i.e., second transistors T2 as described above) of the two pixel circuits 21 arranged in the second direction Y; in a protruding portion L1b and a compensation transistor that are located on a same side of the main body portion L1a, the protruding portion L1b covers two gates of the compensation transistor.

For example, the anode L1 further includes a connection portion L1c that is protruding, and the connection portion L1c is configured to be electrically connected to the pixel circuit 21.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display panel, having a first display region, at least one second display region and a third display region; the at least one second display region being located between the first display region and the third display region, the first display region at least partially surrounding the at least one second display region, and the at least one second display region at least partially surrounding the third display region;
the display panel comprising:
a substrate;
an anode layer disposed on the substrate; the anode layer including a plurality of anodes; and
a pixel definition layer disposed on a side of the anode layer away from the substrate;
the pixel definition layer being provided with a plurality of openings therein, an opening corresponding to an anode, and the opening exposing at least a portion of the anode corresponding thereto;
wherein the first display region, the at least one second display region and the third display region are each provided with openings of the plurality of openings, and aperture ratios of the first display region, the at least one second display region and the third display region sequentially decrease.

2. The display panel according to claim 1, wherein the display panel comprises a plurality of second display regions that are sequentially nested;
aperture ratios of the plurality of second display regions sequentially decrease in a direction from the first display region to the third display region.

3. The display panel according to claim 1, wherein the display panel comprises a plurality of sub-pixels capable of emitting light of a plurality of colors, and the opening is used for defining a light-emitting region of a sub-pixel;
the plurality of openings of the pixel definition layer include first openings, second openings and third openings, the first openings are disposed in the first display region, the second openings are disposed in the at least one second display region, and the third openings are disposed in the third display region;
areas of orthogonal projections, on the substrate, of a first opening, a second opening and a third opening that are corresponding to sub-pixels emitting light of a same color sequentially decrease.

4. The display panel according to claim 3, wherein the display panel comprises a plurality of second display regions that are sequentially nested; in the second openings disposed in the plurality of second display regions, areas of orthogonal projections, on the substrate, of second openings corresponding to sub-pixels emitting light of a same color sequentially decrease in a direction from the first display region to the third display region; and/or
in a plurality of display regions consisting of the first display region, the at least one second display region and the third display region, a difference between areas of orthogonal projections, on the substrate, or openings that are respectively located in every two adjacent display regions and correspond to sub-pixels emitting light of a same color is ΔS, and each ΔS has an approximately equal value.

5. (canceled)

6. The display panel according to claim 1, wherein a distribution density of the openings in the first display region, a distribution density of the openings in the at least one second display region and a distribution density of the openings in the third display region sequentially decrease; and/or
the display panel comprises a plurality of second display regions that are sequentially nested; distribution densities of openings respectively disposed in the plurality of second display regions sequentially decrease in a direction from the first display region to the third display region.

7. (canceled)

8. The display panel according to claim 1, further comprising:
a plurality of pixel circuits disposed between the substrate and the anode layer; a pixel circuit being electrically connected to at least one anode; the plurality of pixel circuits including first pixel circuits, second pixel circuits and third pixel circuits; the first pixel circuits being each electrically connected to at least one anode disposed in the first display region, the second pixel circuits being each electrically connected to anode disposed in the at least one second display region, and the third pixel circuits being each electrically connected to anodes disposed in the third display region;
wherein the at least one second display region includes a setting second display region, a second pixel circuit electrically connected to anodes disposed in the setting second display region is a setting second pixel circuit; a number of the anodes electrically connected to the setting second pixel circuit is greater than a number of anodes electrically connected to a first pixel circuit, and is less than a number of anodes electrically connected to a third pixel circuit.

9. The display panel according to claim 8, wherein the first pixel circuit is electrically connected to one anode, the setting second pixel circuit is electrically connected to two or three anodes, and the third pixel circuit is electrically connected to at least three anodes; and/or
the at least one second display region further includes a general second display region; the general second display region is located between the first display region and the setting second display region, a second pixel circuit electrically connected to at least one anode disposed in the general second display region is a general second pixel circuit; a number of anodes electrically connected to the general second pixel circuit is equal to the number of anodes electrically connected to the first circuit.

10. (canceled)

11. The display panel according to claim 8, wherein the display panel comprises a plurality of sub-pixels capable of emitting light of a plurality of colors, a sub-pixel includes a single anode;
sub-pixels to which the anodes electrically connected to the setting second pixel circuit respectively belong emit light of a same color; and/or sub-pixels to which the anodes electrically connected to the third pixel circuit respectively belong emit light of a same color.

12. The display panel according to claim 11, wherein the setting second pixel circuit is electrically connected to two anodes respectively included in two sub-pixels that are adjacent in a first direction and emit the light of the same color;
the third pixel circuit is electrically connected to four anodes respectively included in four sub-pixels that are adjacent and emit the light of the same color, and the four anodes are arranged in two columns in the first direction, and are arranged in two rows in a second direction;
wherein the first direction is perpendicular to the second direction.

13. The display panel according to claim 1, wherein the display panel comprises a plurality of second display regions that are sequentially nested;
the display panel further comprises a plurality of pixel circuits that are disposed between the substrate and the anode layer;
the plurality of pixel circuits are disposed in the first display region; or
the plurality of pixel circuits are disposed in the first display region and at least one second display region of the plurality of second display regions;
wherein at least one second display region provided with pixel circuits of the plurality of second display regions is closer to the first display region than another at least one second display region provided with no pixel circuit of the plurality of second display regions.

14. The display panel according to claim 13, wherein in a plurality of display regions consisting of the first display region, the at least one second display region and the third display region, a display region provided with pixel circuits of the plurality of pixel circuits is a first transmittance region, and a display region provided with no pixel circuit is a second transmittance region;
the display panel further comprises:
at least one connection layer disposed between the plurality of pixel circuits and the anode layer; the at least one connection layer including a plurality of first connection patterns and a plurality of first connection lines;
wherein the plurality of anodes include a plurality of first anodes and a plurality of second anodes, the plurality of first anodes are disposed in the first transmittance region, and the plurality of second anodes are disposed in the second transmittance region; a first anode is electrically connected to a respective pixel circuit via at least one first connection pattern, and a second anode is electrically connected to a respective pixel circuit via at least one first connection line.

15. The display panel according to claim 14, wherein the display panel comprises a plurality of connection layers; the first anode is electrically connected to the respective pixel circuit via first connection patterns of the plurality of first connection patterns, and the first connection patterns of the plurality of first connection patterns, are respectively located in the plurality of connection layers; orthographic projections, on the substrate, of any two adjacent first connection patterns, that are adjacent in a direction parallel to a thickness direction of the substrate, of the first connection patterns of the plurality of first connections pattern at least partially overlap; and/or
the at least one connection layer includes a first connection layer and a second connection layer, and the first connection layer is farther away from the substrate than the second connection layer; the first connection line used for being electrically connected to the second anode and the respective pixel circuit is located in the first connection layer; and the second connection layer includes a second connection pattern, and the first connection line is electrically connected to the respective pixel circuit via the second connection pattern.

16. (canceled)

17. The display panel according to claim 14, wherein each of at least one pixel circuit is electrically connected to at least two anodes of the plurality of anodes;
the at least one connection layer further includes a plurality of second connection lines, at least two anodes electrically connected to a same pixel circuit are electrically connected to each other via at least one second connection line, and one of the at least two anodes electrically connected to the same pixel circuit is electrically connected to a respective pixel circuit via a first connection pattern or a first connection line.

18. The display panel according to claim 17, wherein the at least one connection layer further includes at least two third connection patterns, and the at least two anodes electrically connected to the same pixel circuit are electrically connected to the at least two third connection patterns, respectively; the second connection line used for being electrically connected to the at least two anodes is disposed in a same connection layer as the at least two third connection patterns, and is electrically connected to the at least two third connection patterns; and/or
the display panel comprises a plurality of connection layers, and the plurality of first connection lines and the plurality of second connection lines are located in different connection layers.

19. (canceled)

20. The display panel according to claim 14, wherein the plurality of pixel circuits include a plurality of circuit units, a circuit unit includes a plurality of first-type pixel circuits and a second-type pixel circuit that are sequentially arranged in a second direction; a first-type pixel circuit is electrically connected to at least one first anode, and the second-type pixel circuit is electrically connected to second anodes of the plurality of second anodes; or
the plurality of pixel circuits include a plurality of circuit units, a circuit unit includes a plurality of first-type pixel circuits and a second-type pixel circuit that are sequentially arranged in a second direction; a first-type pixel circuit is electrically connected to at least one first anode, and the second-type circuit is electrically connected to second anodes of the plurality of second anodes; the display panel further comprises a second initialization signal line and a third initialization signal line; wherein
in the circuit unit, the plurality of first-type pixel circuits are electrically connected to the second initialization signal line, and the second-type pixel circuit is electrically connected to the third initialization signal line.

21. (canceled)

22. The display panel according to claim 3, wherein orthogonal projections, on the substrate, of the first openings are each in a shape of a polygon; orthogonal projections, on the substrate, of the second openings are each in a shape of a polygon, a circle or an ellipse; orthogonal projections, on the substrate, of the third openings are each in a shape of a circle or an ellipse.

23. The display panel according to claim 4, wherein the display panel comprises two second display regions that are nested;
in openings corresponding to the sub-pixels emitting the light of the same color, a ratio of areas of the first opening, a second opening disposed in a second display region closer to the first display region, a second opening disposed in a second display region farther away from the first display region, and the third opening is in a range from 1:0.8:0.6:0.5 to 1:0.9:0.8:0.5.

24. The display panel according to claim 1, further comprising pixel circuit layer disposed between the substrate and the anode layer, wherein the pixel circuit layer includes an active layer, a first gate conductive layer and a second gate conductive layer that are arranged in sequence in a third direction; the third direction is parallel to a thickness direction of the substrate, and is from the substrate to the anode layer;
the pixel circuit layer includes a plurality of pixel circuits, each of at least one pixel circuit includes a compensation transistor; the compensation transistor includes a semiconductor pattern disposed in the active layer and two gates disposed in the first gate conductive layer; the semiconductor pattern includes first portions and a second portion, orthographic projections of the first portions on the substrate overlap with orthographic projections of the two gates of the compensation transistor on the substrate, respectively; an orthographic projection of the second portion on the substrate is located between the orthographic projections of the two gates of the compensation transistor on the substrate; and
the second gate conductive layer includes a first initialization signal line, a light shielding pattern and a connection portion; the connection portion is connected to the first initialization signal line and the light shielding pattern, and an orthographic projection of the light shielding pattern on the substrate overlaps with the orthographic projection of the second portion of the semiconductor pattern on the substrate.

25. The display panel according to claim 24, wherein the pixel circuit further includes a first reset transistor, and the first reset transistor includes two gates disposed in the first gate conductive layer;
each of at least one anode includes a main body portion, and two protruding portions respectively located on two sides of the main body portion in a second direction; an orthographic projection of the main body portion on the substrate is located between orthographic projections of first reset transistors of two pixel circuits arranged in the second direction on the substrate; in the protruding portion and the first reset transistor that are located on a same side of the main body portion, an orthographic projection of the protruding portion on the substrate at least partially overlaps with orthographic projections of the two gates of the first reset transistor on the substrate.

26. A display apparatus, comprising the display panel according to claim 1.
